(19) United States
(12) Patent Application Publication
(10) Pub. No.: US 2017/0098557 A1
(43) Pub. Date: Apr. 6, 2017

(54) PLASMA PROCESSING DEVICE

(71) Applicants: NATIONAL INSTITUTE OF ADVANCED INDUSTRIAL SCIENCE AND TECHNOLOGY, Tokyo (JP); DESIGN NETWORK CO., LTD., Tokyo (JP)

(72) Inventors: Yoshiki SHIMIZU, Tsukuba-shi (JP); Shiro HARA, Tsukuba-shi (JP); Hiroyuki TANAKA, Tsukuba-shi (JP); Shizuka NAKANO, Tsukuba-shi (JP); Hisato OGISO, Tsukuba-shi (JP); Sommawan KHUMPUANG, Tsukuba-shi (JP); Shinji FUTAGAWA, Tokyo (JP); Hideaki YOSHIOKA, Tokyo (JP); Takahiro FUKUDA, Tokyo (JP); Yoshinori UCHIYAMA, Tsukuba-shi (JP)

(73) Assignees: NATIONAL INSTITUTE OF ADVANCED INDUSTRIAL SCIENCE AND TECHNOLOGY, Tokyo (JP); DESIGN NETWORK CO., LTD., Tokyo (JP)

(21) Appl. No.: 15/126,087

(22) PCT Filed: Mar. 10, 2015
(86) PCT No.: PCT/JP2015/057067

§ 371 Date: Sep. 14, 2016

(30) Foreign Application Priority Data
Mar. 14, 2014 (JP) 2014-052630

(51) Int. Cl. H01L 21/67; H01J 37/32; H01L 21/3065

(52) U.S. Cl. CPC H01L 21/67069; H01L 21/3065; H01J 37/32082; H01J 37/32715; H01J 2237/334

(57) ABSTRACT

To provide a plasma device that all functions required for a plasma etching process are incorporated into a narrow space of a minimal fabrication manufacturing device. A plasma processing chamber for performing the plasma etching process on a semiconductor wafer is provided, and a micro-plasma supply section and a lower electrode that superimposes RF on supplied micro-plasma are provided in the plasma processing chamber. A wafer support device that supports the semiconductor wafer supports the semiconductor wafer in the plasma processing chamber during the etching process. The wafer support device is coupled to and supported by a drive section that is arranged outside the plasma processing chamber. The drive section makes the wafer support device repetitively move scanningly in the plasma processing chamber in parallel with a wafer processing surface during the etching process.

### TECHNICAL FIELD

The present invention relates to a processing device suited for a minimal fabrication system that manufactures semiconductor devices and so forth, and particularly to the processing device that is useful for plasma processing.

### BACKGROUND ART

Current semiconductor manufacturing systems have been increased in size and cost of the device itself with an increase in diameter (12 inches and more) of a wafer, and it is estimated that massive capital investment amounting to 300-billion to 500-billion yens is required in order to start up the latest semiconductor factory (a mega fabrication production system). In addition, although a system that uses large diameter wafers is efficient for mass production, when that device is operated for high-mix low-volume production, a manufacturing cost per piece of the number of ones that a user requires becomes extremely high due to problems of the operating ratio and so forth.

Therefore, as a manufacturing system for the semiconductor devices and so forth, a minimal fabrication system that preparation of one device for a 0.5-inch size (a half-inch size. 12.5 mm in diameter exactly) wafer is set as a foundation, each of processing steps that configure the manufacturing system is configured by a portable processing device so as to facilitate rearrangement of those processing devices in a flow shop and a job shop and so forth in accordance with a recipe and thereby to make it possible to appropriately cope with low-volume production and high-mix production is proposed by the applicant of the present invention (Patent Literature 1). In this minimal fabrication system, it is expected that it needs only an extremely small amount of capital investment of about 1/1000 in comparison with the current semiconductor manufacturing system, and it is also expected that it will become a production system suited for high-mix low-volume production for reasons that an operating cost is low and so forth.

Each of the processing devices used in this minimal fabrication system is made to be the one that bears one of individual pieces of processing (in Patent Literature 1, it is defined as “uni-processing”) in processing steps of a semiconductor manufacturing device. They are, for example, a wafer cleaning device, a resist coating device, a wafer exposure device, a plasma processing device, and an ion implantation device. Together with, for example, the coating device, the exposure device or a plasma generation device and so forth that are required for processing thereof, a power source device, a control device and so forth that are required for driving them are incorporated into an internal space of this processing device. Then, these processing devices are arrayed in the order of recipe (the processing flow order) for manufacturing semiconductors. The wafer that is a workpiece is conveyed in order among these arrayed processing devices and corresponding processing is performed thereon by each processing device in order.

Accordingly, this processing device is made portable to such an extent that a man can convey it and has a unified predetermined size so that every time the recipe is changed, the arrangement position thereof can be freely re-arranged conforming to that recipe, and when the arrangement has been changed, its connection with a supply system, a drainage system, a power supply system and so forth that have been regularly arrayed in advance at defined positions on a working floor is possible. The size of this processing device is defined to have external dimensions of width 0.30 m×depth 0.45 m×height 1.44 m, according to the processing device described in the aforementioned Patent Literature 1, not only it is extremely small by itself, but also an occupied floor area thereof is made extremely small in comparison with the existing 12-inch semiconductor manufacturing device even when 60 pieces have been arrayed in accordance with the semiconductor manufacturing recipe.

In addition, one more feature of this minimal fabrication system is that it is made to be the production system that the wafer, which is the workpiece, is conveyed among the processing devices by a unique airtight conveyance system that is substantially shut off from the air outside. Accordingly, it is sufficient that only a predetermined processing space in each processing device be made to be a necessary processing environment such as, for example, a clean room space, an evacuated-state space and so forth, and there is no need to arrange the processing device itself in a clean room. This is the point that is basically different from the existing semiconductor manufacturing system that the semiconductor manufacturing device itself is arranged in a huge clean room. Accordingly, since in this minimal fabrication system, there is no need to arrange the processing device in the clean room, a worker can work in a general work environment, not being forced to work in the clean room. In addition, since there is no need to form the huge clean room, it also leads to energy saving. The minimal fabrication system gathers attention not as the production system that a conventional device has been simply small-sized but as an innovative next-generation production system in this way.

It is required that all the processing devices be processing devices of a unified predetermined size in order to construct the minimal fabrication system for device manufacture in this way. Then, when it is intended to configure a plasma processing device that can be incorporated into the minimal fabrication production system, it is necessary to put all of plasma etching functions into a narrow and small inner space of the processing device having such external dimensions of, for example, width 0.30 m×depth 0.45 m×height 1.44 m as mentioned above. In the conventional plasma processing device that targets on the large diameter wafer as the processing object, the one that an etching gas is uniformly supplied to the entire surface of the semiconductor substrate surface in a pressure-reduced reaction chamber, etching is advanced by plasma discharge, and it is cooled with helium (He) gas and so forth is known (Patent Literature 2). However, in such a plasma processing device, the size of the device itself does not matter so much as the device that targets on the large diameter wafer, the plasma generation device, the power source device therefor and so forth are too large in order to make this to be the processing device to be incorporated into the aforementioned minimal fabrication system.

### CITATION LIST

### Patent Literature

PTL 1: Japanese Patent Application Laid-Open No. 2012-54414

PTL 2: Japanese Patent Application Laid-Open No. 2012-84848

### SUMMARY OF INVENTION

### Technical Problem

Since the processing device to be incorporated into the minimal fabrication system is extremely small not only in storage space for the whole of the device but also in processing space in which various kinds of processing are performed as mentioned above, various kinds of functions should be incorporated into such a narrow and small space. For example, taking the plasma processing device for example, an airtight chamber that accepts the semiconductor wafer should be attached to the extremely narrow and small space in comparison with that of the conventional plasma processing device and control should be made so as to support the semiconductor wafer and to generate plasma in the airtight chamber and so as to perform stable plasma etching. In addition, the power source device, the control device and a gas supply device and so forth therefor should be incorporated together into the processing device. In addition, it should have a conveyance function for surely conveying/holding the small wafer of the half-inch size to/at a predetermined processing position in a processing space. Then, uniform processing should be performed over the entire wafer surface.

However, for example, even when it is intended to incorporate the above-mentioned large diameter plasma generation device into such a narrow and small space and to stably generate highly dense plasma, even the power source device is not stored therein. Accordingly, it is conceived to utilize micro-plasma with which the highly dense plasma can be obtained by a low-output power source in order to cope with such a narrow and small processing space. However, although it is possible to generate the highly dense plasma by the low-output power source, it had never been used in the device manufacturing device so far. The reasons therefor are such that in the micro-plasma, (1) generation of the plasma is isotropic and therefore it results in isotropic etching, (2) although it is not so high in temperature as other thermal plasma, since it is the plasma that involves heat, so-called “resist burning” sometimes occurs, (3) as referred to be just like a flame of a lighter, concentration “fluctuations” occur in the plasma formed and the plasma concentration is unstable, (4) since the generated plasma is a small reaction field, only spot irradiation is possible and it is difficult to uniformly irradiate the whole wafer with it even though it targets on the half-inch size wafer, and further (5) in the common sense of plasma etching in a lithographic technique, a way of thinking that also a spatial distribution of the plasma should be made uniform on the wafer in order to uniformly etch the wafer in-plane region is general, and local utilization of the plasma has never been thought of conventionally. This is mainly because it is thought that the lithographic technique has been developed by specialists of physics and so forth. Furthermore, there is no example that, not limited to the plasma processing device, functions of surely conveying/holding the small half-inch size workpiece to/at the processing position in such a narrow and small airtight chamber, and of uniformly processing the entire processing surface of the workpiece and of cooling the workpiece as required have been incorporated, and that itself is extremely difficult.

The present invention aims to provide a uniform processing device that required wafer (workpiece) processing functions have been incorporated into the small processing space in the minimal fabrication system and that is favorable for the minimal fabrication system, in particular, the processing device that is optimum for micro-plasma processing.

### Solution to Problem

In order to attain the above-mentioned object, the present invention is a processing device for minimal fabrication system having a wafer support device that supports a wafer as a processing object, a wafer hold section that is provided on an upper part of the wafer support device, a processing chamber that houses therein the wafer hold section and is substantially shut off from the outside, and a wafer processing section that is provided in the processing chamber, in which the wafer support device has the wafer hold section, a shaft that supports the wafer hold section and extends to the outside of the processing chamber, a drive section that is connected to the shaft on the outside of the processing chamber and moves the shaft in XYZ axial directions, and a control device that controls the drive section so that processing by the wafer processing unit is made uniform over the entire wafer surface, and the wafer that is held by the wafer hold section is made relatively movable over the entire wafer surface relative to the wafer processing section in the processing chamber by operation of the drive section.

In spite of the narrow and small processing space, it surely supports the wafer (the workpiece) from the outside and the processing device can be uniformly applied over the entire wafer surface in this way. In addition, it is also excellent in wafer cooling efficiency. More specifically, although described in embodiments, since a plasma power source device may be the one that can generate the micro-plasma and is small in output, it can be made to be a small-sized power source device and the space can be exceedingly saved. In addition, since isotropy of the micro-plasma can be improved by superimposing RF on the generated micro-plasma, an etching rate can be improved. In addition, since the workpiece is moved in its processing surface relative to the micro-plasma that is being generated so that processing is performed uniformly, the processing surface of the workpiece can be uniformly processed by plasma even though some fluctuations are generated in the generated plasma. In addition, uniform plasma processing can be performed even by spot irradiation by moving scanningly the workpiece in the processing plane. Even when it is so scanned, a processed area of the workpiece itself is small and therefore there is no need to particularly consider a processing time thereof. To efficiently implement such uniform processing in a short time is impossible for a mega fabrication system that uses the large diameter wafers. Incidentally, scanning used here is different from scanning in a processing device for patterning figures such as an exposure device and so forth. That is, since, in the patterning, it aims to process a non-uniform structure on the workpiece, it is necessary to perform extremely fine scanning control. However, the scanning in the present invention is not scanning for such patterning and is the one that is performed in order to make processing by the processing device perform uniformly in the processing surface of the workpiece and is, for example, the one that makes it move in the XYZ axial directions so as to draw a Lissajous figure relative to the processing device. In addition, since the workpiece and a plasma power supply electrode can be cooled via a workpiece support device, the space is saved in structure and efficient cooling can be performed. Thereby, resist burning can be also prevented.

### Advantageous Effect of the Invention

According to the present invention, there can be provided the processing device that is favorable for incorporating into the minimal fabrication system, the processing device that surely supports the workpiece from the outside of the processing space, in spite of the especially narrow and small processing space, is excellent in cooling efficiency, and compactly configures the function of making uniform processing possible over the entire wafer surface. In particular, in a case where it is applied to the plasma processing device, since the micro-plasma can be effectively used, there can be provided the plasma processing device that is favorable for being incorporated into the minimal fabrication system.

### BRIEF DESCRIPTION OF DRAWINGS

FIG. 1 is an outside perspective view when a plasma processing chamber 12 of a plasma processing device M according to the present embodiment is viewed from above.

FIG. 2 is a conceptual diagram of the plasma processing device M.

FIG. 3 is an essential part side view of the plasma processing device M.

FIG. 4 is an essential part perspective view of a wafer support device 19.

FIG. 5 is a perspective view of a wafer pedestal 20.

FIG. 6 are essential part exploded perspective views showing an operation of the wafer support device 19.

FIG. 7 is a perspective view of a drive mechanism.

FIG. 8 (a) is a perspective view showing the bottom of the plasma processing chamber 12 and a state under it, and FIG. 8 (b) is an essential part longitudinal sectional diagram.

FIG. 9 is an outside perspective view of the plasma processing device M to be incorporated into a minimal fabrication system.

FIG. 10 illustrates another embodiment (1) relevant to the present embodiment. FIG. 10(a) is a perspective view of a wafer support table 22, and FIG. 10(b) is a longitudinal sectional diagram of the periphery of the wafer support table 22 on which the wafer is mounted.

FIG. 11 illustrates another embodiment (2) relevant to the present embodiment. FIG. 11 is a longitudinal sectional diagram of the periphery of the wafer support table 22.

FIG. 12 are explanatory diagrams showing efficacy of the plasma processing device of the present invention, in which FIG. 12(a) is a diagram explaining the efficacy of superimposition of RF on micro-plasma, and FIG. 12(b) is a diagram explaining that uniformity of an in-plane etching rate is improved in association with scanning of the wafer.

FIG. 13 is a schematic diagram showing a plasma processing device according to a first mode related to the present invention.

FIG. 14 is an explanatory diagram showing a state where the wafer is being etched by the above-mentioned plasma processing device.

FIG. 15 are outside views showing a housing where the above-mentioned plasma processing device is to be housed, in which FIG. 15(a) is a front view, FIG. 15(b) is a right side view and FIG. 15(c) is a rear view.

FIG. 16 is a schematic perspective view showing a nozzle used in the above-mentioned plasma processing device.

FIG. 17 is a schematic perspective view showing another mode of the above-mentioned nozzle.

FIG. 18 is a schematic diagram showing a plasma processing device according to a second mode related to the present invention.

FIG. 19 is a schematic diagram showing part of a plasma processing device according to a third mode related to the present invention.

FIG. 20 is a schematic diagram showing a plasma processing device according to a fourth mode related to the present invention.

FIG. 21 is an explanatory diagram showing a state where the wafer is being etched by the above-mentioned plasma processing device.

FIG. 22 is a schematic diagram showing a plasma processing device according to embodiments 1 to 6 related to the present invention.

FIG. 23 are diagrams showing scanning conditions by the plasma processing device according to the above-mentioned embodiments 1 to 6, in which FIG. 23(a) is a distance R movements from an initial position, and FIG. 23(b) is rotational scanning of a radius R.

### DESCRIPTION OF EMBODIMENTS

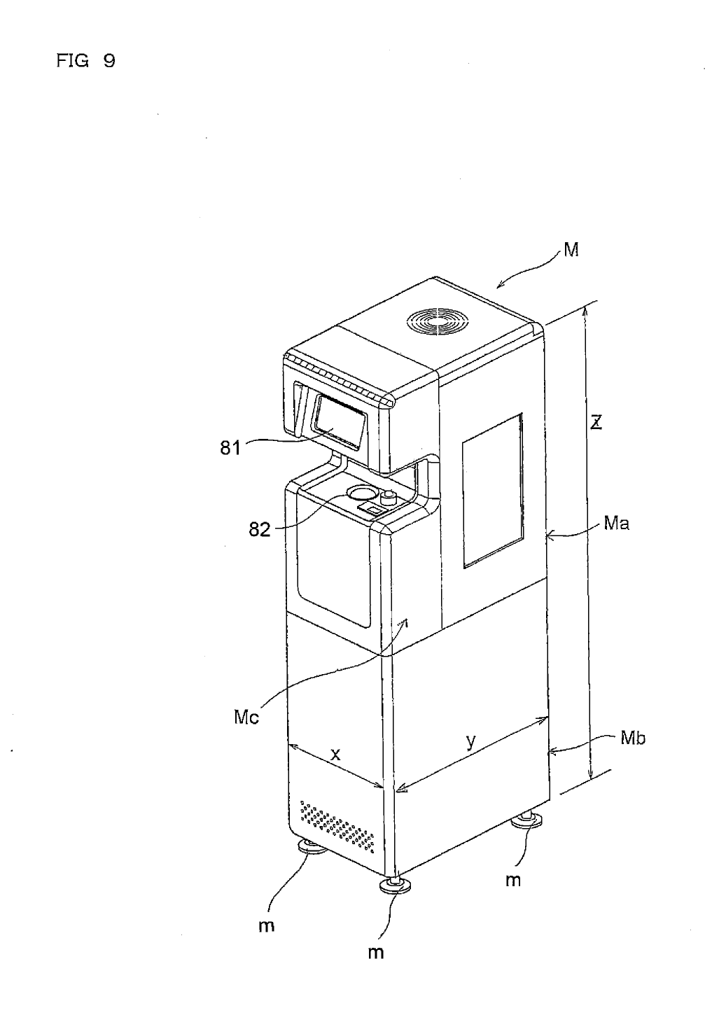

In the following, embodiments of the present invention will be described in detail. First, in the embodiments of the present invention, a processing device for a minimal fabrication system will be described, taking a plasma processing device for an example. The entire configuration of the plasma processing device M will be described using FIG. 9. This plasma processing M is made to be width (×) 0.30 m×depth (y) 0.45 m×height (z) 1.44 m in external form to the same as other processing devices in the aforementioned minimal fabrication system. This plasma processing device M includes a Main body section Ma that stores the plasma processing chamber 12, and a control storage section Mb that stores a power source device and a control device, a gas supply device and so forth. In addition, a front chamber Mc that conveys a wafer into the plasma processing chamber in the main body section Ma is provided on a front part of the plasma processing device M. The front chamber Mc is configured to be the one that has a conveyance function and an external shape that are common among all of other processing devices of the minimal fabrication system. Support sections m that position and hold the plasma processing device M at a predetermined position on the floor are provided on a lower part of the plasma processing device M.

Semiconductor wafers (workpieces) 18 to be processed by the plasma processing device M are stored in wafer storing shuttles (not shown) one by one and conveyed to the plasma processing device M. The shuttle is configured so that one sheet of the semiconductor wafer of 0.5 inch in diameter (a half-inch size. 12.5 mm in diameter correctly) is stored in a state of being substantially shut off from the air outside.

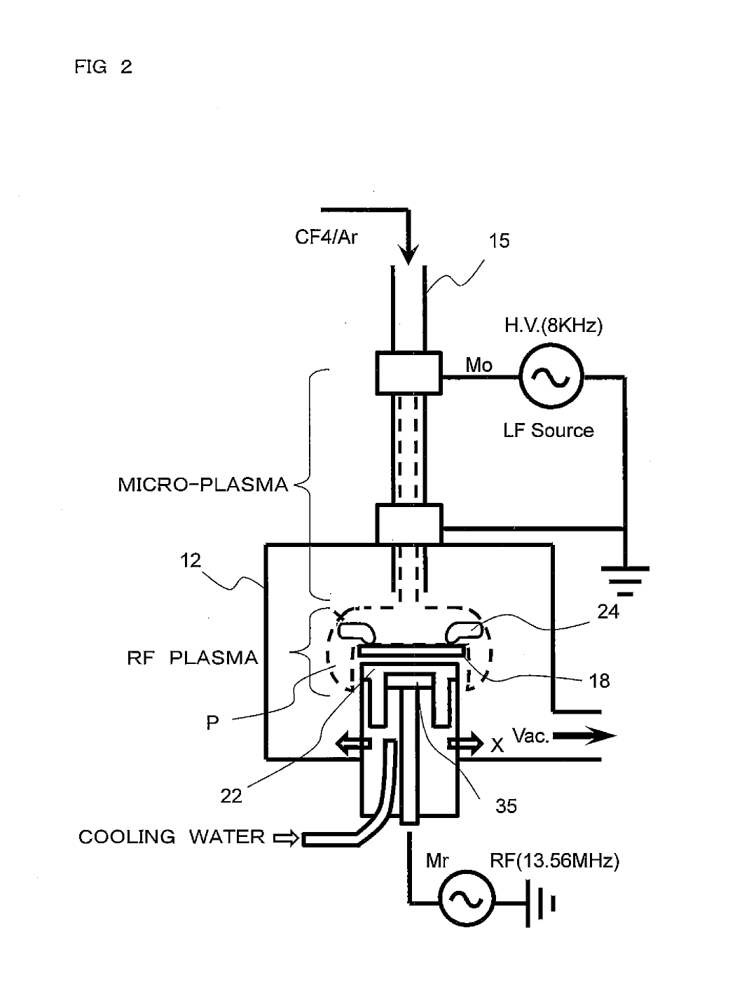

A docking port 82 that connects the front chamber Mc with the shuttle is provided in an upper part of the front chamber Mc. A wafer conveying space that connects it to the docking port 82 is provided in the front chamber Mc, and the wafer conveying space is configured to be capable of being brought into a high vacuum state by a high vacuum pump. In addition, an air-tight gate valve 14 is provided between the wafer conveying space and the plasma processing chamber 12 (FIG. 2). Furthermore, a conveyance mechanism (not shown), which takes out the wafer 18 in the shuttle on the docking port 82 in a state of being shut off from the air outside, makes the taken out wafer 18 pass through the gate valve 14 that is door-opened and conveys it up to the wafer support device 19 in the plasma processing chamber 12, is provided in the wafer conveying space. Incidentally, a display system operation panel 81 is provided above the front chamber Mc.

As mentioned above, a sealed-type conveyance mechanism (Particle-Lock Airtight Docking: PLAD system), which consists of the shuttles and the conveyance mechanism that is provided in the front chamber Mc and so forth and substantially shuts off minute particles and gas molecules from the external environment, is provided in this minimal fabrication system. The semiconductor wafer 18 that serves as a target is carried from another processing device into the front chamber Mc via the shuttle, and is carried in onto the wafer support device (a workpiece support device) 19 in the plasma processing device 12 by the PLAD system. Then, the semiconductor wafer 18 that has been plasma-etched on the wafer support device is carried out (returned) into the shuttle on the docking port 82 also by the PLAD system. The semiconductor wafer 18 after plasma-processing is stored into the shuttle and is conveyed to the next processing device in accordance with the recipe.

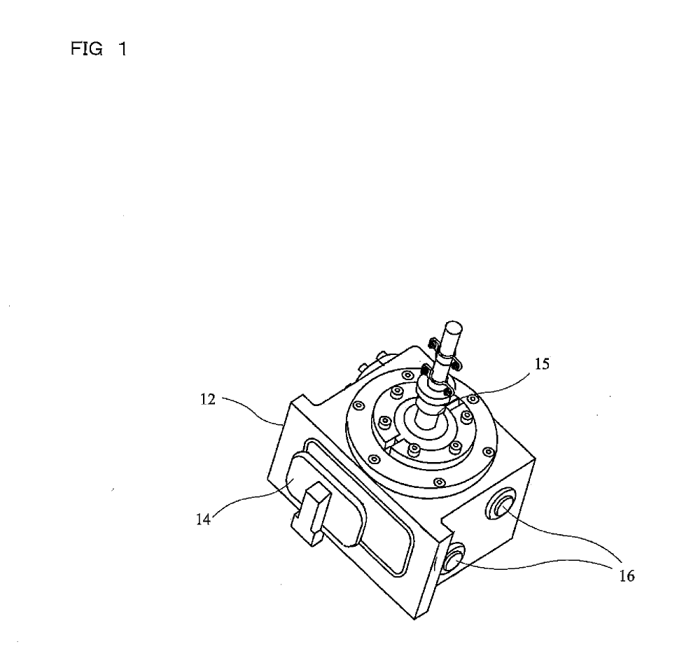

The outside appearance of the plasma processing chamber is shown in FIG. 2. The gate valve 14, through which the semiconductor wafer 18 is taken in and out between it and the front chamber Mc, is provided in this plasma processing chamber 12. The gate value 14 is configured so that it serves as a wafer gateway that communicates with the front chamber Mc, and the inside of the plasma processing chamber 12 can be maintained at a predetermined degree of vacuum. Furthermore, a gas supply port 15, through which an activated gas such as CF₄ and so forth is supplied into it, and a gas exhaust port 16 is provided in the plasma processing chamber 12. They are mechanisms for supplying and exhausting an etching gas. Also facilities to supply these gases are housed in the inner space of the plasma processing device M shown in FIG. 1.

A plasma generation mechanism in the plasma processing chamber 12 will be described using FIG. 1. A micro-plasma generation device Mo, configured so that tubular electrodes are provided on a CF₄/Ar gas supply tube at intervals of about several centimeters and a predetermined high voltage is applied between them, is arranged on an upper part of this plasma processing chamber 12. In the present embodiment, an applied voltage was 8 KHz, 7 kV in peak value, 20 W in output. The micro-plasma generated by this micro-plasma generation device Mo is supplied into the plasma processing chamber 12.

Furthermore, an RF plasma device Mr adapted to superimpose RF on the supplied micro-plasma is arranged in the plasma processing chamber 12. This RF plasma device Mr is the one configured so that a lower electrode 35 is provided under the wafer support table 22, on which the wafer 18 is to be mounted, and an AC current is applied to the lower electrode 35. In the present embodiment, a high frequency applied is 13.56 MHz, 25 to 50 W, a degree of vacuum is 100 Pa. As described above, in the plasma processing device M in the present embodiment, it is configured so that after the micro-plasma has been generated, RF can be further superimposed on that micro-plasma. Owing to this configuration, a micro-plasma jet P that has been made small in plasma characteristic length is generated in the plasma processing chamber 12.

Furthermore, in order to uniformly irradiate the semiconductor wafer 18 with the generated micro-plasma jet P, the wafer support table 22 is configured to be moved scanningly in parallel (that is, in an X direction shown in FIG. 1. In a direction that is parallel with the wafer support table 22) with a processed surface of the mounted semiconductor wafer 18. A configuration for making it move scanningly will be described later.

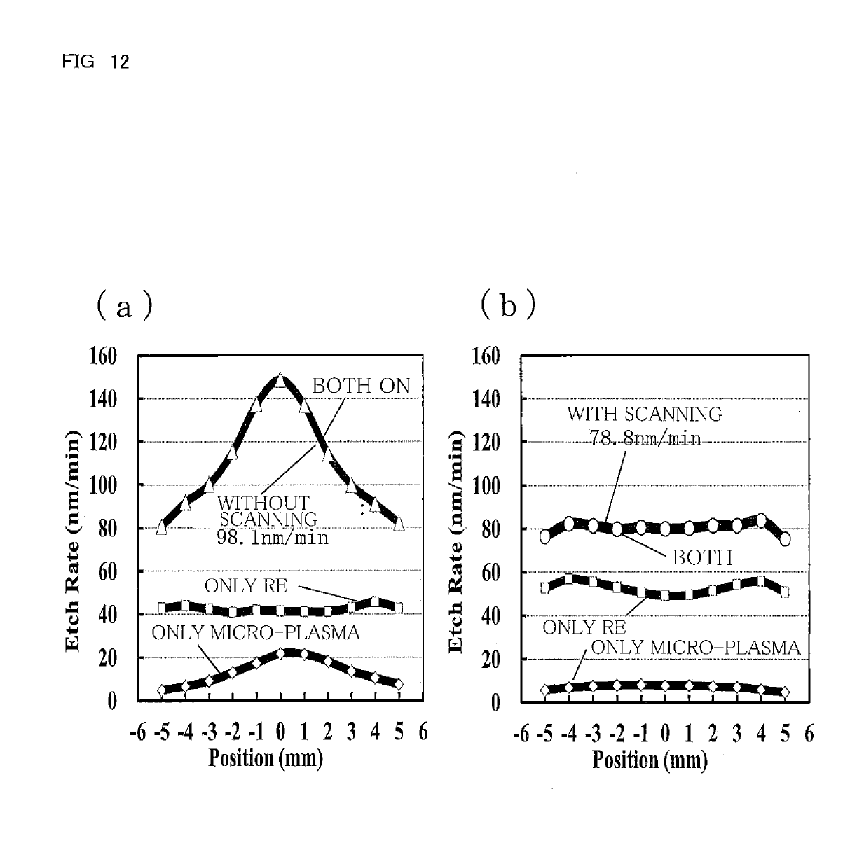

Here, etching characteristics of the plasma processing device M configured as mentioned above will be described. As shown in FIG. 12, a wafer position was plotted on the horizontal axis, an etching rate was plotted on the vertical axis, and the aforementioned RF superimposition effect and a scanning effect of the wafer support table 22 were examined. Since the wafer diameter is 12.5 mm, the radius 6.25 mm is set as a wafer edge. The wafer is fixed by a clamp 24, and there is a pressing margin of the clamp 24 across the 0.5 mm width from the outermost periphery. Thus, data on a region to 5 mm from the center was plotted at intervals of 1 mm.

As shown in FIG. 12(a), in regard to an RF addition effect, in a case where only the micro-plasma has been turned ON, a distribution of small protrusions appeared at an average etching rate of about 10 nm/min. In addition, in case of only the RF plasma has been turned ON, a flat wafer in-plane etching rate distribution of about 40 nm/min was obtained. In contrast, in a case where both have been turned ON, although it became a Gaussian distribution-like shape as shown in the graph, an etching rate that is obviously larger than the total sum of the two kinds of plasma was obtained. That is, it is seen that a synergistic effect has emerged by adding together these two kinds of plasma.

As shown in FIG. 12(b), in regard to a stage scanning (XY scanning) effect, although the in-plane etching rate distribution in a case of no stage scanning exhibited the Gaussian distribution-like shape, non-uniformity was improved by 3.5% by performing stage scanning. Accordingly, it is seen that stage scanning had a dramatic effect.

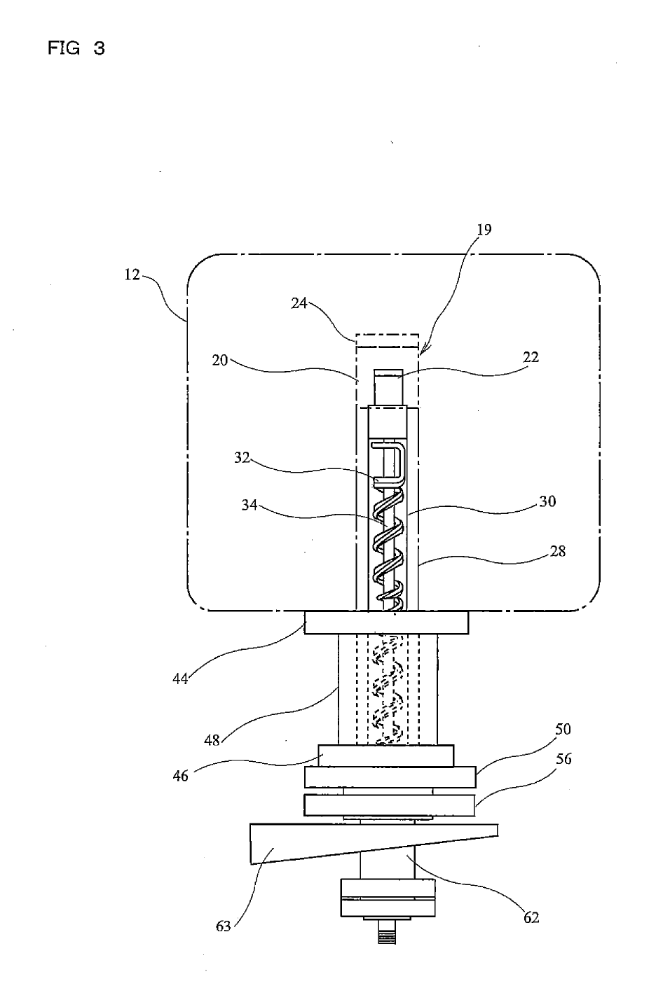

FIG. 3 is a side view of essential parts including the plasma processing chamber 12. A one-point chain line in the drawing indicates an outer wall surface position of the plasma processing chamber 12. The outside view of the plasma processing chamber 12 is not shown. The lower side of the plasma processing chamber 12 is indicated as a schematic side view. An upper end of the wafer support device 19 protrudes into the plasma processing chamber 12 so as to pass through a bottom plate thereof. The wafer support device 19 is provided with a wafer hold section for gripping and holding the semiconductor wafer 18 on an upper end thereof, and a part under the wafer hold section is made to be a shaft that extends to the outside of the plasma processing chamber 12. The wafer hold section consists of the wafer pedestal 20, the wafer support table 22 and a wafer pressing plate 24, and in these, the wafer pedestal 20 is fixed to an upper end of a protective tube 28, which forms the outermost side of this shaft, and is supported at a predetermined position in the processing chamber. Then, a cylindrical through port 20a that passes in an up-down direction is provided in a central part of the wafer pedestal 20, and the wafer support table 22 that moves up and down relative to the wafer pedestal 20 is provided in the through port 20a. An upper end surface of the wafer support table 22 is made to be a mounting surface for mounting the semiconductor wafer 18 at a processing position, and it is configured so as to support the semiconductor wafer (workpiece) 18 (not shown in FIG. 3) by clamping it by the wafer support table 22 and the wafer pressing plate 24 that has been provided above the wafer support table 22. A wafer grip mechanism that consists of these wafer pedestals 20, wafer support table 22 and wafer pressing plate 24 and so forth will be described later in more detail.

Furthermore, the protective tube 28 is provided under the wafer pedestal 20 so as to be contiguous to the wafer pedestal 20, and a refrigerant supply tube 30, a cooling tube 32, a power supply body 34, the lower electrode 35 (not shown in FIG. 3) are provided in the protective tube 28. The refrigerant supply tube 30 is provided so as to cover the cooling tube 32 and is configured so as to supply a refrigerant to the cooling tube 32. The powder supply body 34 is provided so as to supply power to the lower electrode 35, and the cooling tube 32 is configured so as to be wound around the power supply body 34 to cool the power supply body 34 and the lower electrode 35 and so as to cool the refrigerant that is supplied to the refrigerant supply tube 30. Thereby, the semiconductor wafer 18 on the wafer support table 22 is cooled with the refrigerant in the refrigerant supply tube 30. All of the protective tube 28 that supports the wafer pedestal 20, the refrigerant supply tube 30 that supports the wafer support table 22, or the cooling tube 32 and so forth are configured by stainless steel pipes and so forth. In addition, it is favorable that the wafer support table 22 is configured by a material that is high in cooling effect relative to the semiconductor wafer 18 to be mounted thereon, for example, ceramic and so forth. In FIG. 3, only the outline of the wafer pressing plate 24, the wafer pedestal 20 and the protective tube 28 was indicated by a one-dot chain line, and only the outline of the refrigerant supply tube 30 was indicated by a solid line. In addition, the inside of the protective tube 28 was shown by a broken line and illustration of a part under it was omitted.

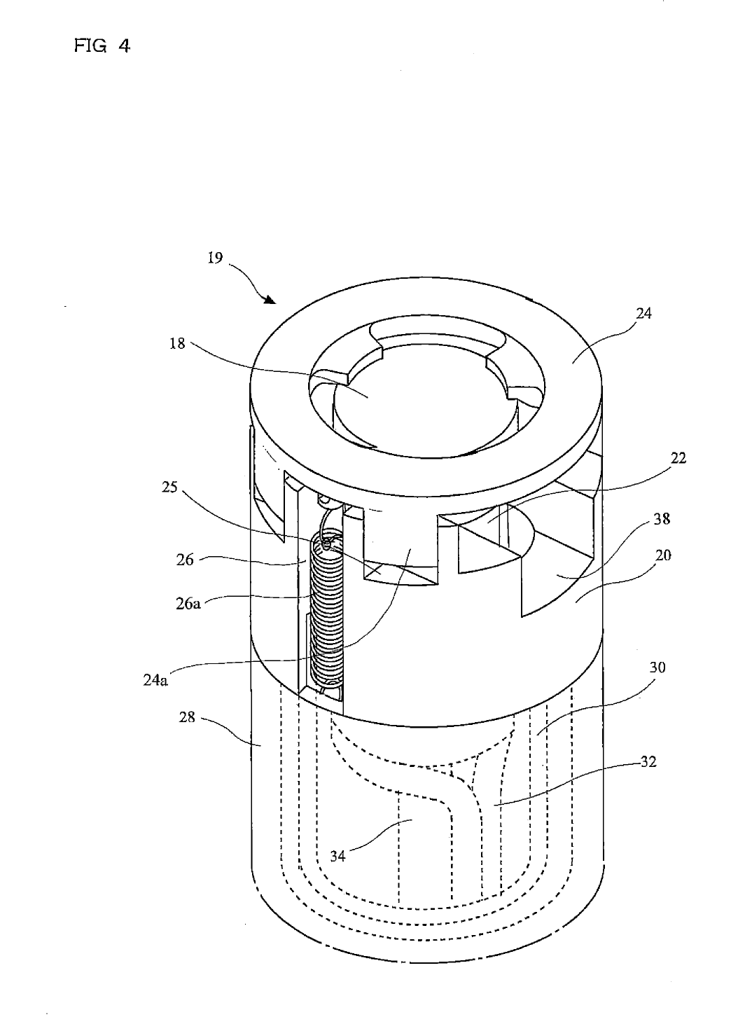

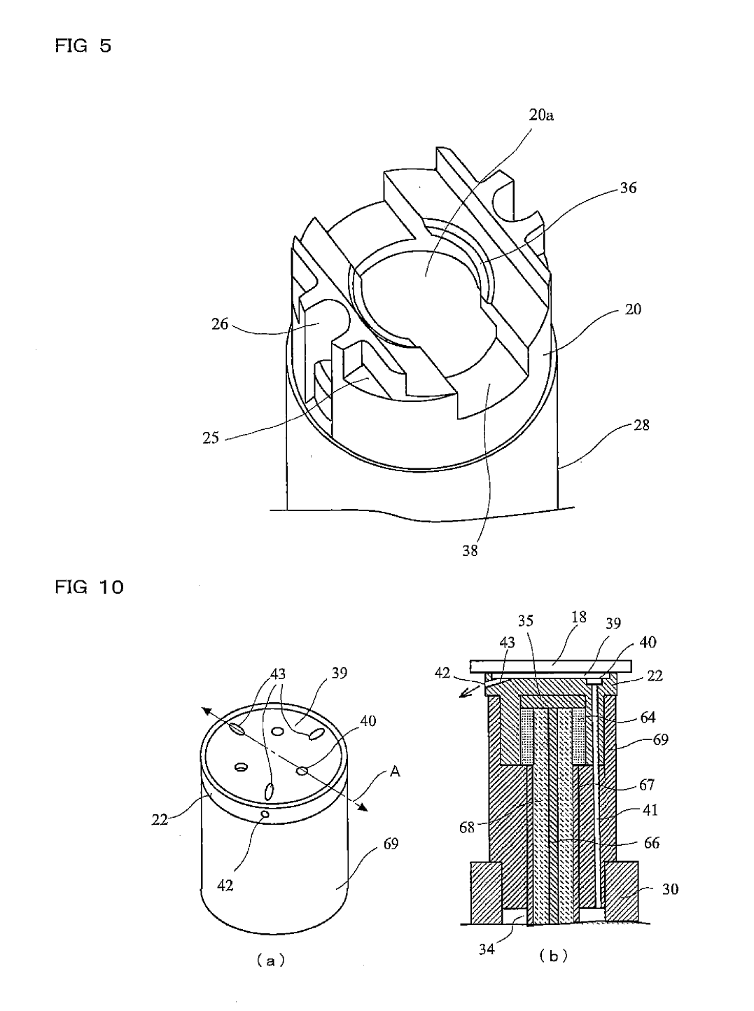

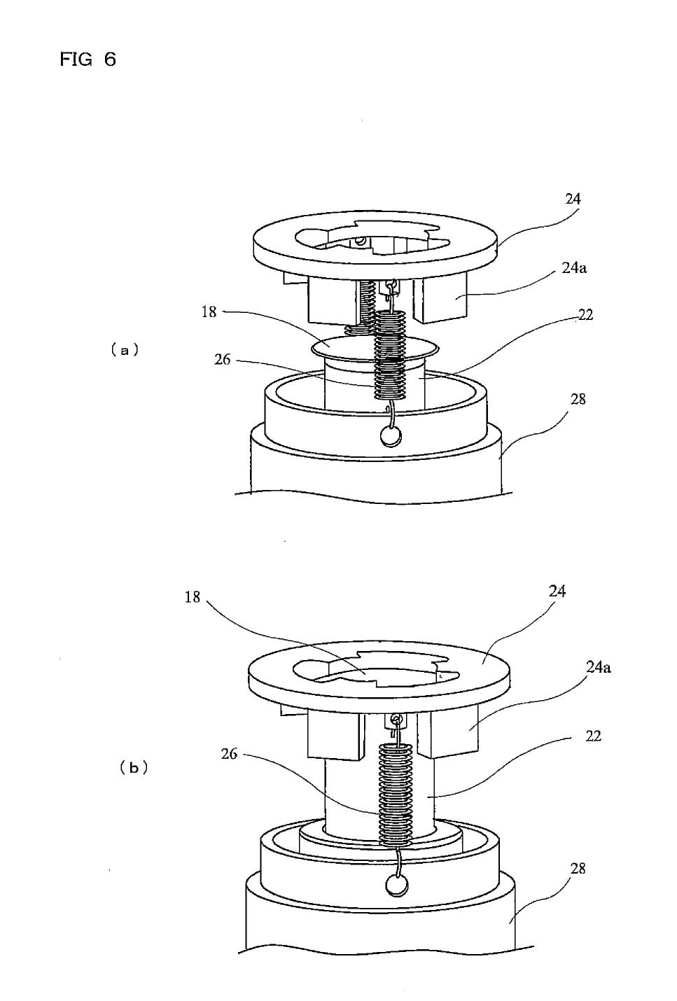

FIG. 4 is an essential part perspective view of the wafer support device 19. FIG. 5 is a perspective view of the wafer pedestal 20. FIG. 6 are essential part exploded perspective views showing an operation of the wafer support device 19. In the following, the wafer grip mechanism by the wafer hold section, which has been provided on the upper end part of the wafer support device, will be described by using these FIGS. 4 to 6. As shown in FIG. 4, the wafer hold section, that is, the wafer pedestal 20, the wafer support table 22 and the wafer pressing plate 24 are provided at the upper end part of the wafer support device 19. In these, the wafer pedestal 20 is fixed to the upper end of the protective tube 28 and is supported at a predetermined position in the processing chamber. In addition, the cylindrical through port 20a is provided in its central part, and a wafer hold groove (a wafer mount) 36, into which the half-inch size semiconductor wafer 18 fits, is provided in an upper end part of the through port 20a in an almost half-moon shape. Furthermore, a groove 38 for an arm, which extends down to a side surface of the wafer pedestal 20 so as to cross the through port 20, is formed in the wafer pedestal 20 downward more deeply than the wafer hold groove 36.

In addition, the shaft of the wafer support table 22 is inserted into the through port 22a of the wafer pedestal 20, and the wafer support table 22 is configured to be movable in the up-down direction relative to the wafer pedestal 20 so that an upper end surface thereof can be positioned at an upper position and a lower position relative to the wafer hold groove 36. Furthermore, a guide groove 25, which guides a leg part 24a of the wafer pressing plate 24, and a groove 26, which is configured to store therein a spring 26a that applies tensile force to both the wafer pressing plate 24 and the wafer pedestal 20, are provided in a side surface of the wafer pedestal 20 in the up-down direction.

As shown in FIG. 4, the wafer pressing plate 24 is configured to slide in a direction that the wafer support table 22 moves up and down along the guide groove 25 in the wafer pedestal 20. The wafer pressing plate 24 is coupled with the upper end of the protective tube 28 by the spring 26a as shown in FIG. 6. The wafer pressing plate 24 presses the peripheral part of the semiconductor wafer 18 in the wafer support table 22 direction by elastic force of this spring 26a. The semiconductor wafer 18 conveyed by an arm (the one that configures part of the aforementioned PLAD system. Not shown), which extends from the front chamber Mc, fits into the wafer hold groove 36. The groove 38 for the arm is adapted to make the arm pass through it. Thereby, a leading end part of the arm, which extends from the front chamber Mc passing through the gate valve 14, enters the groove 38 for the arm, and can access to the semiconductor wafer 18 that fits into the wafer hold groove 36 without colliding with the wafer pedestal 20 (or the leading end part of the arm carries the semiconductor wafer 18, which is held on the leading end part, into the wafer hold groove 36 without colliding with the wafer pedestal 20 and thereafter can return to the front chamber Mc safely). Incidentally, both of the wafer pressing plate 24 and the wafer pedestal 20 are configured by ceramic moldings.

FIG. 6 are essential part exploded perspective views showing the operation of the wafer support device 19. This drawing shows a state where the wafer pedestal 20 has been removed, in which FIG. 6(a) shows a state directly after it has accepted the semiconductor wafer 18 and FIG. 6(b) shows a state where the wafer support table 22 has lifted up the semiconductor wafer 18 and pressed it against the wafer pressing plate 24. In the state of FIG. 6(b), it is well seen that the spring 26a slightly extends, and the wafer support table 22 and the wafer pressing plate 24 clamp the semiconductor wafer 18. RF plasma is generated by the lower electrode 35, which is present directly under this wafer support table 22, and an etching process is performed.

As shown in FIG. 6, the wafer support table 22 moves up and down so as to press the semiconductor wafer 18, which has been received in the wafer hold groove (the wafer mount) 36 in the wafer pedestal 20 from a PLAD arm, against the wafer pressing plate 24. The wafer pressing plate 24 is configured so as to slide in the direction that the wafer support table 22 moves up and down along the guide groove 25 in the wafer pedestal 20. The wafer pressing plate 24 is coupled with the upper end of the protective tube 28 by the spring 26a. The wafer pressing plate 24 presses the peripheral part of the semiconductor wafer 18 in the wafer support table 22 direction by the elastic force of this spring 26a. The wafer pedestal 20 receives the semiconductor wafer 18, which has been carried into it by the arm in its wafer hold groove 36, and the wafer support table 22 scoops up the wafer, which has been inserted into the wafer hold groove in the wafer pedestal 20 and clamps, fixes and supports the semiconductor wafer 18 in cooperation with the wafer pressing plate 24 in this way. Subsequently, the wafer support table 22 holds the semiconductor wafer 18 at a predetermined height in the processing chamber (FIG. 6(b)) and the etching process is performed on the semiconductor wafer 18. In this way, since in the present embodiment, the semiconductor wafer 18, which has been conveyed into the plasma processing chamber 12, is fixed and supported by the both wafer support table 22, which moves up and down in the plasma processing chamber 12, and the wafer pressing plate 24 that follows the wafer support table 22 in this way, it can surely hold it at the predetermined position in spite of the simple mechanism.

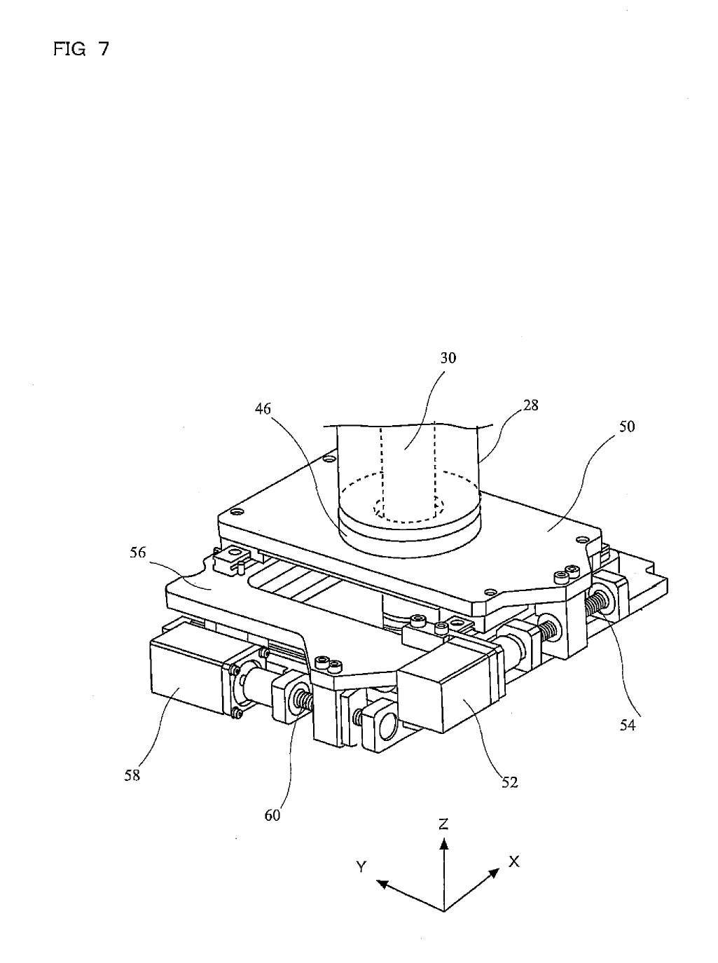

As described before, it was found that the RF plasma that is supplied into the plasma processing chamber can be effectively and uniformly utilized by not only making the semiconductor wafer 18 stand still in the center of the plasma processing chamber 12 shown in FIG. 1, but also making it move scanningly in the plasma processing chamber 12 during the etching process. However, it is difficult to house the drive mechanism in the plasma processing chamber 12 that is formed extremely small. Thus, in the present invention, it is configured to drive the wafer support table 22 by the drive mechanism that has been provided outside the plasma processing chamber 12. Next, this drive mechanism will be described using FIG. 3 and FIGS. 7, 8.

As shown in FIG. 3, the wafer support table 22 is supported in the refrigerant supply tube 30 and the wafer pedestal 20 is supported in the protective tube 28. Furthermore, the refrigerant supply tube 30 is supported so that it can freely move in the protective tube 28 in its axial direction. In the refrigerant supply tube 30, an inert gas such as helium and so forth, the cooling tube 32 that houses therein the refrigerant such as cooling water and so forth for cooling this inert gas, and the power supply body 34 for supplying power to the lower electrode 35 for discharge are housed. This refrigerant is supplied so as to be supplied from the drive mechanism side to the lower electrode 35 side and then returned again to the drive mechanism side.

A hole is provided in a base plate of the plasma processing chamber 12 within a range that the protective tube 28 is movable in the XYZ directions, and an upper ring 44 is attached around that hole. The protective tube 28 is extended downward passing through this upper ring 44. A lower ring 46 is connected to the upper ring 44 down below it, through the intermediary of an external cylinder 48 that is flexibly deformable. The protective tube 28 passes through the upper ring 44 and the external cylinder 48 and the lower ring 46 and a lower end thereof is connected and fixed to a lifting device 62. Sealing for maintaining air-tightness of the plasma processing chamber 12 is applied between the lower ring 46 and the protective tube 28.

As shown in FIG. 3 and FIG. 7, the lower end of the refrigerant supply tube 30 is fixed to the lifting device 62 passing through the lower ring 46 and a first drive plate 50 and a second drive plate 56. The inner parts of the protective tube 28 and the external cylinder 48 and the lifting device 62 are pressure-reduced similarly to the inner part of the plasma processing chamber 12. The refrigerant and the inert gas are supplied from a lower end of the lifting device 62 into the protective tube 28. The protective tube 28, the lower ring 46, the first drive plate 50 and the lifting device 62 are coupled and fixed together, and move fore and aft and right and left in the XY plane as will be descried later. In the present embodiment, the wafer support table 22, the semiconductor wafer 18, the power supply body 34 and so forth can be efficiently cooled simultaneously. In addition, since the wafer support table 22 is supported by the refrigerant supply tube 30, which houses therein the power supply body 34, and the protective tube 28 that houses therein the refrigerant supply tube 30, the semiconductor wafer 18 and the wafer support table 22 can be efficiently cooled, and a support structure of the semiconductor wafer 18 can be configured compactly and firmly. Furthermore, as shown in FIG. 3, since the refrigerant supply tube 30 can be made to be the long one that reaches under the plasma processing chamber 12, the cooling gas can be sufficiently cooled by using the cooling tube 32.

The wafer support table 22 is moved by the lifting device 62 in an axial direction (the Z-axis direction in FIG. 7) of the protective tube 28. The first drive plate 50 makes a first drive screw 54 rotate with a first motor 52 and makes the protective tube 28 move in a direction (the X-axis direction in FIG. 7) that intersects with the shaft thereof. The second drive plate 56 makes a second drive screw 60 rotate with a second motor 58 and makes the first drive plate 50 move in a direction (the Y-axis direction in FIG. 7) that intersects with the shaft thereof. A control device (not shown), adapted to drive the first drive plate 50 and the second drive plate 56, is provided so that the semiconductor wafer 18 uniformly comes into contact with the inert gas for etching in the plasma processing chamber 12. The first drive plate 50 and the second drive plate 56 make the protective tube 28 move in the XY axis directions by the control device so that the semiconductor wafer is uniformly exposed to the micro-plasma in the plasma processing chamber 12. Although it does not matter whether a driving pattern for moving it in the XY axis directions is a circular movement or a zigzag movement, when it is a moving method that an irradiation region of the plasma on the wafer does not stop during plasma irradiation, for example, a pattern that makes it move scanningly so as to draw a Lissajous curve, more efficient and uniform plasma processing is possible. Such extremely fine scanning movement as that of a drawing device is not required. Accordingly, the drive device, which consists of the first drive screw 54, the first drive plate 50, the second drive screw 60, the second drive plate 56 and so forth, and the control device therefore are configured so that the XY axial direction movements of the protective tube 28 may be made simply as course movements. Incidentally, the second motor 58 and the second drive screw 60 are fixed to a Z-axis direction drive plate 63 of the minimal processing device body shown in FIG. 3.

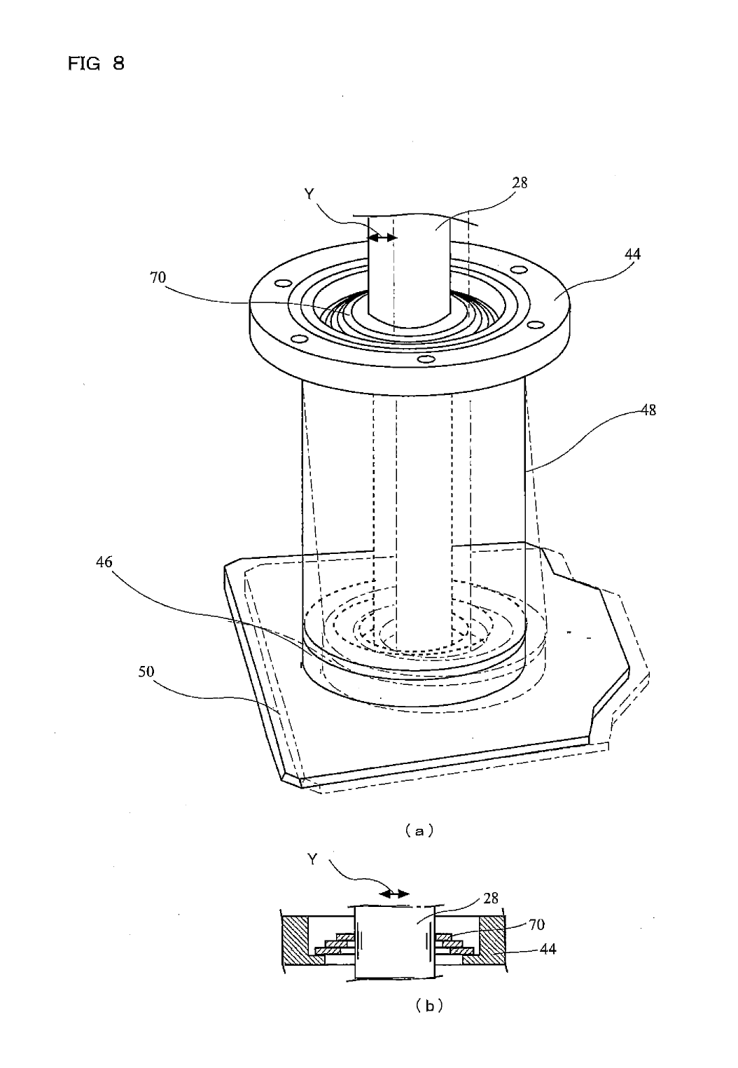

FIG. 8(a) is perspective view showing the upper ring 44 fixed around a hole in the bottom of the plasma processing chamber 12 and a state under it. In this FIG. 8(a), an operation when the protective tube 28 has moved from a solid-line state to a one-point chain line is exemplified. When the first drive plate 50 moves, the protective tube 28 fixed to this moves. It shows a state where the external cylinder 48 obliquely deforms at this time. A hole that is sufficiently large in comparison with the diameter of the protective tube 28 is provided in the upper ring 44 and allows a movement of the protective tube 28 in the horizontal direction (the XY directions) in FIG. 7. The lower ring 46 is driven by the first drive plate 50 and the second drive plate 56, and moves in a plane of the XY axis directions described in FIG. 7. Although the upper ring 44 is fixed to the plasma processing chamber 12 (FIG. 3) and does not move, the external cylinder 48 flexibly deforms and absorbs the movement thereof. It is favorable that the external cylinder 48 be of a flexible structure such as a pressure hose. Thereby, the wafer support table 22 can displace in the x, Y directions comparatively freely and makes scanning movement possible. Since, in the present embodiment, the wafer support device 19 that supports the semiconductor wafer is made to move scanningly by coupling to the drive mechanism that has been arranged outside the plasma processing chamber 12 in this way, favorable plasma processing becomes possible even by the narrow and small plasma processing chamber 12.

A longitudinal sectional diagram of a central part of the upper ring 44 has been shown in FIG. 8(b). A plurality of movable washers 70 are provided so as to fill up the gap between the upper ring 44 and the protective tube 28 in the embodiment shown in the FIG. 8. The movable washers 70 are configured by a plurality of washers whose opening sizes are different from one another little by little and these washers are piled up by shifting them in the horizontal direction with no gap. Thereby, the movements of the protective tube 28 in the XY axis directions are not disturbed and in addition a falling object from above can be surely received. A foreign matter in the plasma processing chamber 12 can be prevented from falling into the external cylinder 48 by this movable washer 70. For example, even though when the semiconductor wafer 18 is put on the wafer pedestal 20, the semiconductor wafer 18 collides with something and falls, the movable washer 70 facilitates collection by holding it in the plasma processing chamber 12. Since a shielding member that consists of the aforementioned movable washers 70 is made movable following scanning movement in this way and thereby the workpiece is surely conveyed to the processing position and is extrapolated in close contact with the shaft, even when, for example, the workpiece has fallen from a workpiece support surface from any cause, it can be received by the shielding member and therefore taking out of the workpiece that has fallen is facilitated.

In regard to a cooling mechanism that cools the wafer support table 22, the semiconductor wafer 18, and the lower electrode 35 and so forth, also another embodiment (1) such as that shown in FIG. 10 will do, other than the above-mentioned embodiment. FIG. 10(a) is a perspective view of the wafer support table 22, and FIG. 10(b) is a longitudinal sectional diagram being cut in an arrow A direction in FIG. 10(a), showing that the wafer support table 22 with the semiconductor wafer 18 put on it. As shown in FIG. 10(a), a depression 39 for cooling the semiconductor wafer 18 is provided in an upper surface of the wafer support table 22. Several cooling ports 40 and upper holes 43 are opened in the depression 39. Then, the upper holes 43 communicate with exhaust holes 42 provided in a side surface of the wafer support table 22. As shown in FIG. 10(b), the cooling port 40 is joined with the inner part of the refrigerant supply tube 30 via a vent 41 provided in the wafer support table 22 and an external electrode 69. In addition, the upper hole 43 that is provided facing the depression 39 communicates with the exhaust hole 42 provided in the side surface and a communication passage thereof is formed obliquely downward. Accordingly, the cooling gas that is flew out through the exhaust hole 42 is flew out downward below the semiconductor wafer 18 that is mounted on the wafer support table 22 as shown in FIG. 10(b).

As shown in FIG. 10(b), the power supply body 34 is removed by a predetermined length of an external conductor 67 at a terminal thereof. The external conductor 67 is electrically connected to the external electrode 69. In addition, an internal conductor 66 is electrically connected to the lower electrode 35 in the center. The lower electrode 35 is insulated from the external electrode 69 by the wafer support table 22 and an insulation spacer 64. A voltage required for RF plasma generation is applied between the internal conductor 65 and the external conductor 67 of the power supply body 34, and the RF plasma is generated above the wafer support table 22 by an electric field that is formed between the lower electrode 35 in the center and the external electrode 69.

Owing to the above-mentioned configuration, the cooling gas that has been injected into the refrigerant supply tube 30 flows into the depression 39 through the cooling port 40 that opens to the depression 39 via the vent 41. Accordingly, the cooling gas spreads in the depression 39 and can directly cool the rear surface of the semiconductor wafer 18. Then, the cooling gas, which has cooled the rear surface of the semiconductor wafer 18 and has been raised in temperature, is flew out through the upper hole 43, via the exhaust hole 42, obliquely downward into the plasma processing chamber 12. Since the semiconductor wafer 18 is fixed by being clamped by the wafer support table 22 and the wafer pressing plate 24 by such a mechanism as that shown in FIG. 4 in this way, the etching process can be advanced while directly cooling over the wide area of the lower surface of the semiconductor wafer 18 with the cooling gas. Accordingly, since the semiconductor wafer 8 can be directly cooled, it is better in cooling efficiency than cooling that is done simply by heat conduction. In addition, also the external electrode 69 is cooled with the cooling gas that passes through the vent 41. Furthermore, since the external electrode 69 is in contact with the internal conductor 66 of the power supply body 34, heat can be radiated by heat conduction. Furthermore, since the cooling gas that is flew into the plasma processing chamber 12 is emitted downward below the semiconductor wafer 18 that has been mounted on the wafer support table 22, it does not influence the plasma processing of the semiconductor wafer 18 with the RF plasma.

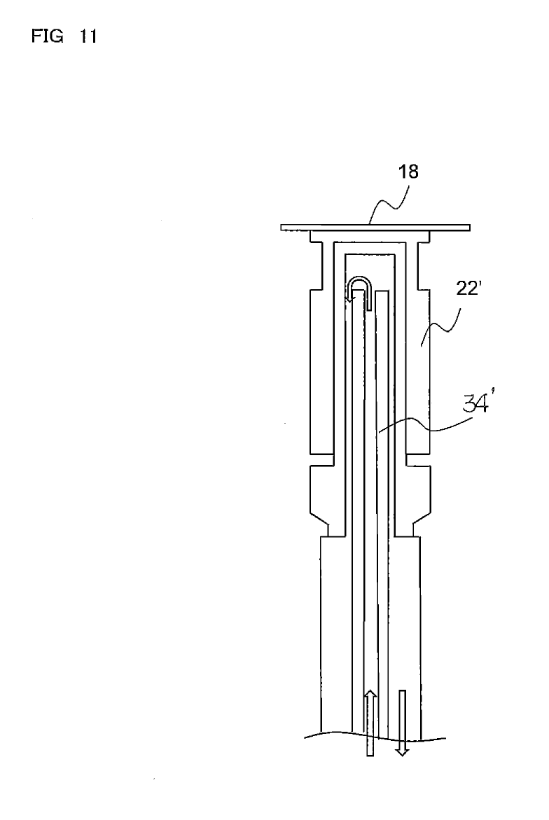

In regard to the cooling mechanism that cools the wafer support table 22′, the semiconductor wafer 18 and the lower electrode 35 and so forth, also another embodiment (2) such as that shown in FIG. 11 will do in addition to the above-mentioned embodiment. FIG. 11 is a longitudinal sectional diagram of a wafer support mechanism that includes a wafer support table 22′. As shown in FIG. 11, the semiconductor wafer 18 is mounted on a wafer mounting surface of the wafer support table 22′. The lower electrode and a power supply body 34′ for RF plasma generation are integrally configured and support the wafer support table 22. The lower electrode and the powder supply body 34′ are of a two-layer structure having an inner tube in an outer tube and are configured so that a space part in the inner tube and a gap between the inner tube and the outer tube that covers it serve as a passage of a cooling medium. Accordingly, the cooling medium for cooling the lower electrode and the power supply body 34′ is supplied, for example, as shown by arrows, from within an inner tube into the power supply body, passes through the gap between the inner tube and an outer tube, and is flew out to the outside. Accordingly, the lower electrode and the power supply body 34′ are directly cooled with the cooling medium and the semiconductor wafer 18 is indirectly cooled via the wafer support table 22′ that is in contact with the lower electrode. Thereby, since a structure is made so that the electrode itself is made to be a lower structure of the wafer support device 19 and the cooling medium flows into the electrode, cooling of the electrode can be effectively performed in spite of the simple structure, and therefore efficient cooling of the semiconductor wafer 18 can be performed, although cooling of the semiconductor wafer 18 is indirectly performed. Furthermore, in the present embodiment, resist burning that is peculiar to the micro-plasma can be avoided and cooling of the electrode and securement of the strength of the wafer support mechanism can be done because it has the function of supplying power to the lower electrode 35 and the function of cooling the semiconductor wafer 18 and the power supply body 34. Incidentally, in this embodiment (2), although the power supply body and an electrode section are formed integrally, they are not necessarily integrated and any structure will do, as long as the electrode is directly connected to the power supply body so as to bring the refrigerant into contact with the electrode lower part.

In the embodiment of the present invention, the etching process is performed as follows by using the device of the above mentioned configuration. At first, the gate valve 14 (FIG. 2) of the plasma processing chamber 12 is opened and the semiconductor wafer 18 is sent into the plasma processing chamber 12 by the arm of a not shown PLAD conveyance device. The arm conveys the semiconductor wafer 18 along the groove 38 for the arm (FIG. 5) of the wafer pedestal 20 and puts the semiconductor wafer 18 in the wafer hold groove (the wafer mount) 36, configured in the wafer pedestal 20. Then, the arm withdraws along the groove 38 for the arm. Thereafter, the wafer support table 22 moves up from below the wafer pedestal 20 as shown in FIG. 6, presses the semiconductor wafer 18 against the wafer pressing plate 24 and supports the semiconductor wafer at the predetermined height position.

After preparation for the etching process has been made as described above, the inside of the plasma processing chamber 12 and the inside of the external cylinder 48 are pressure-reduced and the gas for etching is supplied into the gas supply port 15 while driving the micro-plasma generation device Mo. Thereby, the micro-plasma is supplied into the micro-plasma processing chamber 12. Thereafter, power is supplied to the lower electrode 35 via the power supply body 34 to make the RF plasma to be generated around the semiconductor wafer 18. Thereby, the etching process is started. The semiconductor wafer 18, the lower electrode 35 and so forth, whose temperatures are raised by RF plasma discharge, are cooled with the refrigerant such as the inert gas and so forth supplied via the refrigerant supply tube 30. The inert gas is continuously supplied in a state of having been sufficiently cooled in contact with the cooling tube 32.

The semiconductor wafer 18 that is supported on the wafer support table 22 moves scanningly in the direction intersecting with the axis of the protective tube 28 in the plasma processing chamber 12 during the etching process. After the etching process has been terminated, the wafer support table 22 moves down and the semiconductor wafer 18 returns to a state of being housed in the wafer hold groove 36 configured in the wafer pedestal 20. Thereafter, the gate valve 14 of the plasma processing chamber 12 is opened and the semiconductor wafer 18 is taken out by the not shown arm.

In the above-mentioned embodiment, although in regard to the shielding member that fills up the gap between the upper ring 44 and the protective tube 28, the plurality of movable washers 70 whose opening sizes are different from one another little by little are used, other embodiments such as the one that, for example, a bellows that flexibly deforms in a sliding direction is used, can be also used, not limited to this. In addition, although in the above-mentioned embodiment, the wafer pressing plate 24 is pressed against the wafer support table 22 by using the spring 26a, other embodiments such as the one of a configuration where, for example, the wafer pressing plate 24 is pressed against it by its own weight without using the spring 26a, can be also used, not limited to this. In addition, although in the above-mentioned embodiment, the gas to be supplied through the gas supply port 15 was the CF₄/Ar gas, it goes without saying that it can be applied to other gases for plasma etching not limited to this. In addition, although in the above-mentioned embodiment, the inert gas is used as the cooling refrigerant, it goes without saying that other refrigerants for cooling such as, for example, cooling water and so forth can be used, not limited to this. Furthermore, although the above-mentioned embodiment is optimum by applying it to the plasma processing device (the so-called minimal fabrication system) for the semiconductor wafer 18 of the half-inch size, it is apparent that it is applicable to a general size semiconductor wafer, not limited to this. In addition, it is apparent that the processing object is not limited to the wafer and it is also applicable to workpieces other than the wafer-shaped one such as a three-dimensional IC and so forth. Although in the above-mentioned embodiment, the wafer processing section has been made to be the plasma processing device, the wafer processing section may be made also as, for example, a sputtering device, an SEM inspection device, a wafer surface spray coating device, or a CVD device and so forth. In these processing sections, uniform processing can be performed on the entire surface of the wafer processing surface by relatively performing scanning on the entire surface of the wafer processing surface.

Although the embodiments of the present invention have been described as mentioned above, the present invention is not limited to the above-mentioned embodiments and can be embodied by appropriately modifying within a range not deviating from the gist thereof.

The present embodiment has the support function of surely supporting the semiconductor wafer 18 in the extremely narrow and small plasma processing chamber 12, and the scanning movement function of efficiently and uniformly performing the etching process even when the concentration fluctuations have been generated in the generated plasma and moreover implements these functions by the extremely simple structure. Then, although it is optimum to use the processing device having this wafer supporting function and/or the scanning function in the micro-plasma processing device, it is apparent that it can be used for other plasma processing or other semiconductor processing, for example, a sputtering process and so forth, not limited to the micro-plasma processing. Thereby, wafer (workpiece) holding in the extremely narrow and small processing chamber and conveyance to the processing position (or from the processing position) can be surely performed, and cleanness in the processing chamber can be improved by providing the drive mechanism outside the processing chamber and the space that should be maintained in a clean environment can be compactly configured. Moreover, safety securement of the wafer (the workpiece) in the processing chamber by the aforementioned movable washers 70 and the external cylinder 48, and securement of the degree of freedom when scanning become possible.

Next, modes related to the present invention will be described on the basis of the drawings.

### [First Mode]

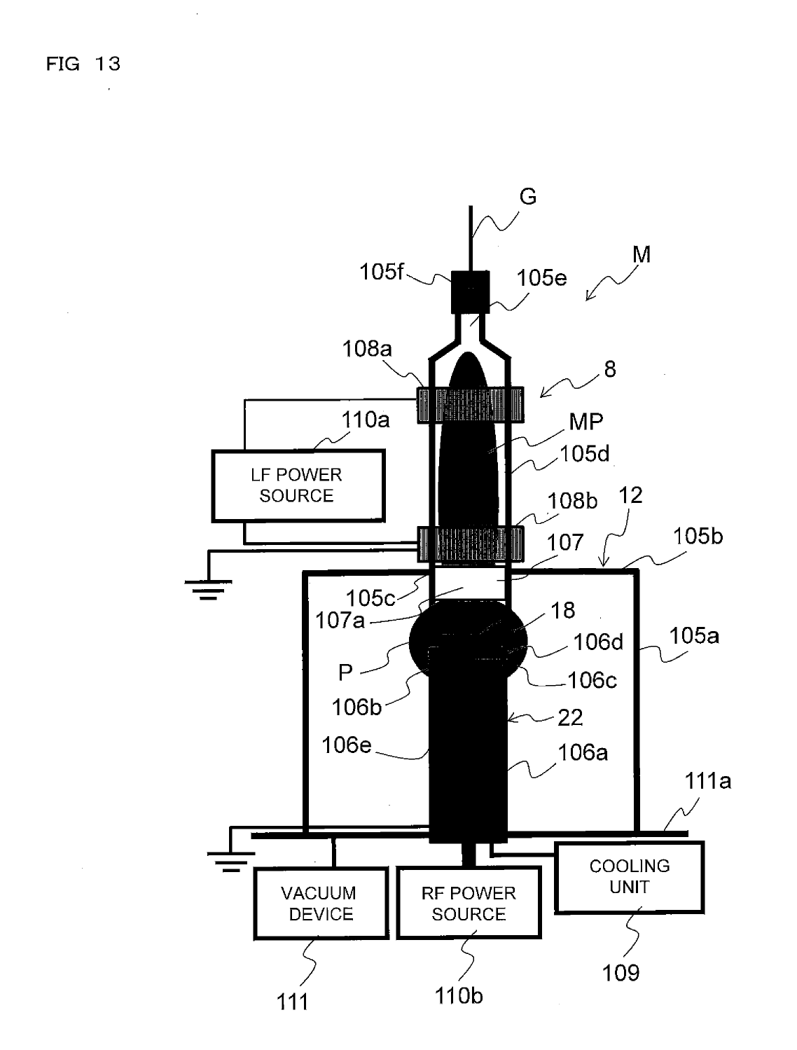

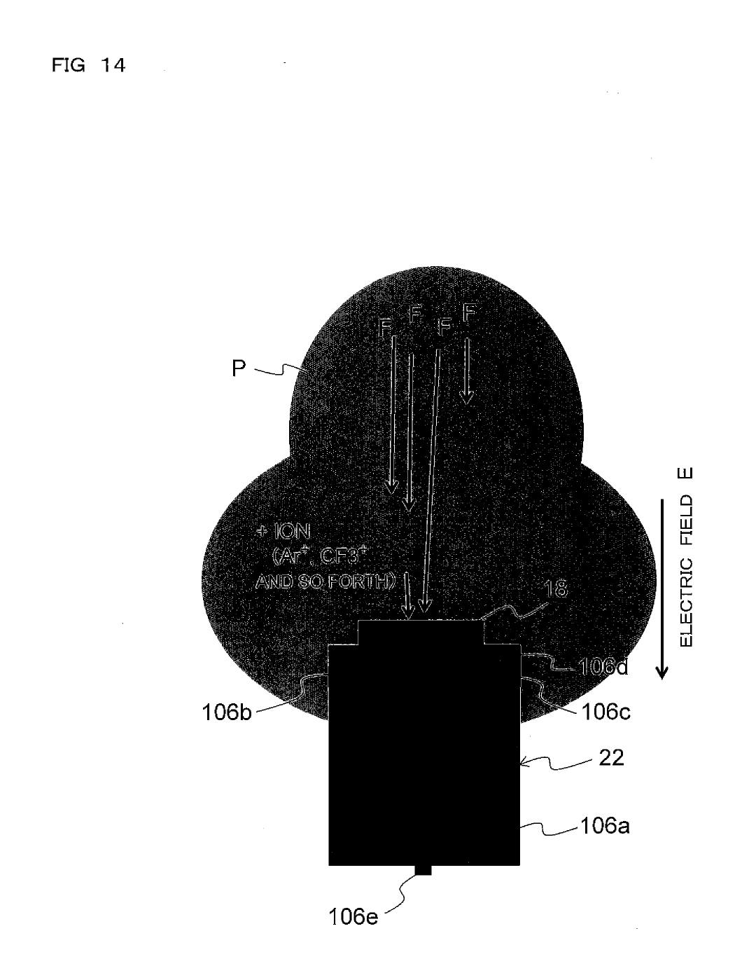

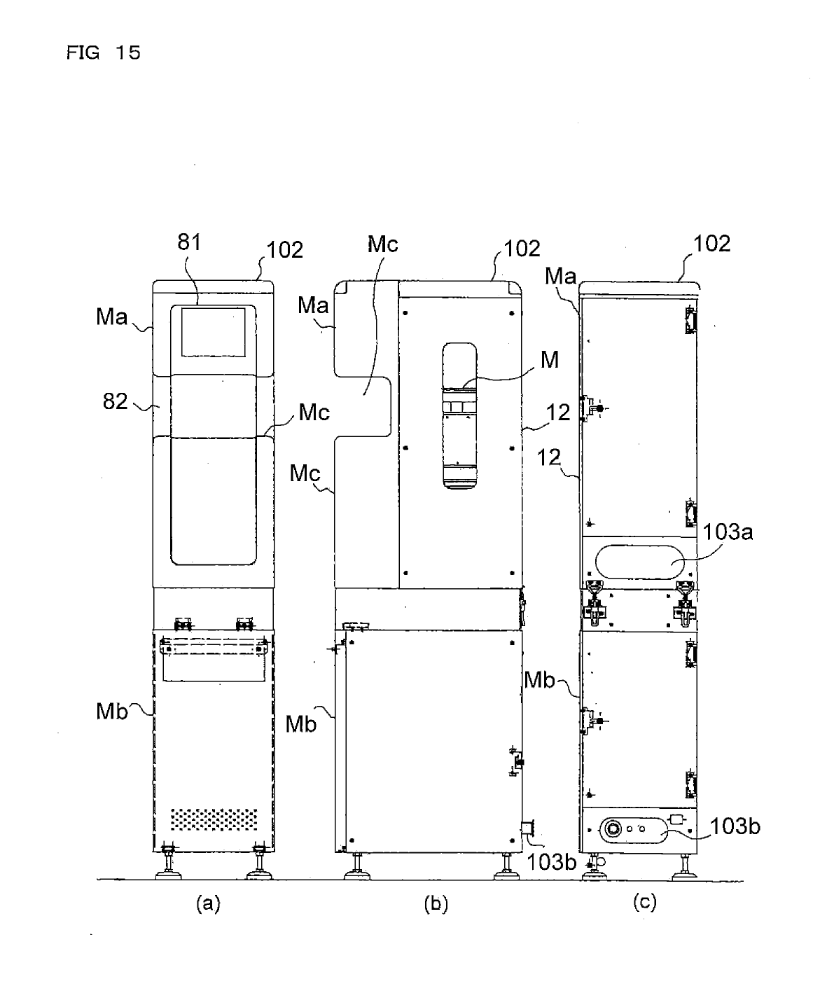

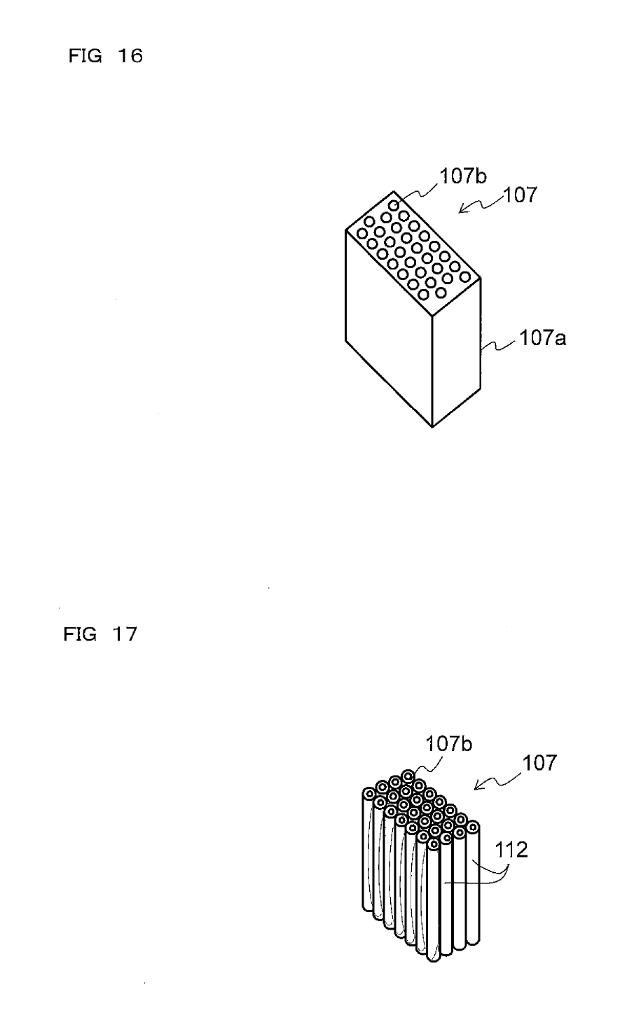

FIG. 13 is a schematic diagram showing a plasma processing device according to the first mode related to the present invention. FIG. 14 is an explanatory diagram showing a state where the wafer is being etched by the plasma processing device. FIG. 15 are outside views showing a housing that the plasma processing device is housed, in which FIG. 15(a) is a front view, FIG. 15(b) is a right side view, and FIG. 15(c) is a rear view. FIG. 16 is a schematic perspective view showing a nozzle used in the plasma processing device.

The plasma processing device M according to the first mode related to the present invention is a minimal fabrication plasma etching device, which is housed in a housing 102 of the size that has been defined in advance and is based on a minimal fabrication concept as shown in FIG. 15. Here, this minimal fabrication concept is optimum for the multi-mix low-volume semiconductor manufacturing market, can cope with various types of resources saving, energy saving, investment saving, high performance fabrication and implements a minimal production system of minimalizing the production that has been described, for example, in Japanese Patent Application Laid-Open No. 2012-5441.

In addition, the housing 102 is a module that is formed into an almost rectangular parallelepiped shape having a longitudinal direction in the up-down direction and is of a structure that shuts out each of the minute particles and the gas molecules. The plasma processing device M adapted to etch the wafer 18 is housed in the main body section Ma as a device upper part on the upper side of this housing 102. Here, as plasma etching by the plasma processing device M, there is the one that etches the surface of the wafer 18 by corresponding to a resist pattern that is laminated on the surface of the wafer 18.

A supply section 103 and so forth adapted to supply, for example, an etching gas G and so forth used for plasma etching by this plasma processing device M is provided on a rear surface of the main body section Ma under the plasma processing device M. Preparation of this etching gas G and so forth is performed in the outside of the housing 102 and the gas G is then supplied into the plasma processing device M via the supply section 103a.

Furthermore, a control storage section Mb, which is a device lower part for building therein the control device and so forth to control the plasma processing device M in the main body section Ma, is provided on the lower side of the housing 102. A cooling unit 109, a power source unit 110 and so forth used in etching by the plasma processing device M are housed in this control storage section Mb. In addition, a gas exhaust section 103b, which serves as an outlet to make gases flow out, such as the etching gas G and so forth after used when etching by the plasma processing device M, to the outside of the housing 102, is provided in the rear surface of the control storage section Mb. Then, this gas exhaust section 103b is connected to a tank (not shown) and so forth for accumulating the gases flew out from this gas exhaust section 103b.

In addition, the front face side of the main body section Ma is made in the form that has been notched upward into a recessed shape in an intermediate part in the up-down direction of the main body section Ma of the housing 102. Then, the operation panel 81 is attached to the upper-side front face side of this main body section Ma. In addition, a lower-side part of this main body section Ma is made to be a front chamber Mc for carrying the wafer 18 into the housing 102. Then, the almost circular docking port 82 as a shuttle housing section for installing the minimal shuttle (not shown) as a conveyance container is provided on an almost central part of the upper surface of this front chamber Mc. Here, the front chamber Mc is configured to respectively shut out each of the minute particles and the gas molecules into the housing 102. That is, this front chamber Mc is made to be a PLAD (Particle Lock Air-tight Docking) system that allows the wafer 18 to be housed in the minimal shuttle to be taken into/out of the housing 102 without exposing it to the air outside and so forth.

Then, the conveyance device (not shown) for conveying the wafer 18 that is carried into it through the docking port 82 to a predetermined position of the plasma processing device M and carrying out the wafer 18 after etched by this plasma processing device M to the docking port 82 is housed in the front chamber Mc. Incidentally, as the conveyance device, a workpiece conveyance device and so forth described, for example, in Japanese Patent Application Laid-Open No. 2011-96942 are used.

### <Plasma Processing Device>

Next, the plasma processing device M is housed in the plasma processing chamber 12 as the wafer processing chamber on the rear-side upper part of the front chamber Mc in the housing 102. Then, the wafer to be etched by this plasma processing device M is formed into a disk-shape that has a circular surface of a predetermined size, for example, 12.5 mm in diameter (the half-inch size) and is configured by single crystal silicon (Si). Then, a predetermined resist pattern is formed in advance on the surface of this wafer 18 and is set in a pre-plasma-etching state.

Furthermore, the plasma processing device M is the one that has used both of a so-called LF micro-plasma system and a stage RF plasma system. That is, this plasma processing device M is the one that performs vertical etching by applying a low-frequency voltage to an LF application section 108 attached to a later described gas supply tube 105d to make a large amount of fluorine radicals (F) to be generated in the etching gas G, applying a high-frequency voltage to an RF application plate 106d attached to the wafer support table 22 to make an ion sheath to be generated, and throwing the large amount of fluorine radicals (F) into the surface of the wafer 18 almost vertically together with plasma ions (CF₃⁺, Ar⁺) generated by exciting and ionizing CF₃ and Ar in the etching gas G.

Specifically, this plasma processing device M possesses the plasma processing chamber 12, which is the chamber, and the wafer support table 22 as the stage to be installed in this plasma processing chamber 12 as shown in FIG. 13, and has such a configuration where this wafer support table 22 is air-tightly covered with the plasma processing chamber 12.

### <Chamber>

The plasma processing chamber 12 is configured by a transparent material that makes application of the low-frequency voltage from the outside possible such as, for example, quartz glass and so forth. Then, this plasma processing chamber 12 has a cylindrical main body section 105a, is installed by setting an axial direction of this main body section 105a along the up-down direction, and the upper end side of this main body section 105a is in the form that has been closed by a disk-shaped upper plate 105b. In addition, a rectangular opening 105c is formed in a central position of this upper plate 105b, and the lower-end side of, for example, a rectangular cylindrical gas supply tube 105d as a gas supply section is concentrically fitted into and attached to this opening 105c. This gas supply tube 105d is formed into a rectangular tubular shape in section having an outer size that is smaller than an inner size of the main body section 105a and is slightly larger than an outer size of the wafer 18, is set in a state where part of the lower end side of this gas supply tube 105d is internally fitted into the opening 105c from the outer side of the upper plate 105b, and is integrally attached to this opening 105c by being welded thereto and so forth. Here, as the shape of the gas supply tube 105d, also shapes other than the rectangular cylindrical shape, for example, a cylindrical shape and so forth may be acceptable.

A block-shaped nozzle 107 is attached to the lower end part of the gas supply tube 105d by being internally fitted into it. This nozzle 107 possesses a square pillar-like main body section 107a having an outer size that is almost equal to an inner size of the gas supply tube 105d. This main body section 107a is formed so that a longitudinal size of the end face in the up-down direction is slightly larger than the outer-diameter size of the wafer 18. In addition, a plurality of gas insertion through holes 107b is pierced in this main body section 107a as shown in FIG. 16. These gas insertion through holes 107b are linearly formed along a height direction of the main body section 107a, are set in a state where these gas insertion through holes 107b are separated from one another in parallel and at equal intervals, and are provided by making them linearly penetrate through the main body section 107a from one end surface to the other end surface thereof. That is, these gas insertion through holes 107b are provided over the entire of the nozzle 107 and a configuration is made so that the etching gas G is sprayed to the wafer 18 almost uniformly by making it pass through the respective gas insertion through holes 107b of this nozzle 107.

In addition, a gas supply port 105e is joined to an upper part of the gas supply tube 105d. Here, as the gas supply port 105e, it may be formed by concentrically reducing the diameter of an upper end part of the gas supply tube 105d and, in addition, a branch tube (not shown) may be provided to the gas supply tube 105d and it may be provided by connecting it to this branch tube. Specifically, a metal tube 105f is attached to the gas supply port 105e and the etching gas G such as, for example, a mixed gas (CF₄/Ar) of carbon tetrafluoride and argon (Ar) is supplied into the plasma processing chamber 12 through the gas supply port 105e via this metal tube 105f. Incidentally, as the etching gas G, it can be made to be a gas configured only by carbon tetrafluoride (CF₄).

In addition, an LF application section 108, which is a nozzle plasma generation section for making micro-plasma (minute plasma that is on the order of μm to mm in diameter) MP to be generated in the etching gas G to be sprayed to the wafer 18 via this gas supply tube 105d, is provided in the gas supply tube 105d. This LF application section 108 is a radical generation section, which makes the micro-plasma MP to be generated in the etching gas G to be sprayed from the nozzle 107 to the wafer 18 so as to make the large amount of fluorine radicals (F) originated from this micro-plasma MP to be generated. Specifically, this LF application section 108 has electrode sections 108a, 108b respectively attached to the upper side and the lower side of a part that protrudes upward from the upper plate 105b of the gas supply tube 105d. Here, the lower-side electrode section 108b is attached to a lower-end side edge of the part that protrudes upward from the upper plate 105b of the gas supply tube 105d. In addition, these electrode sections 108a, 108b are configured into a coil-like shape by winding a copper wire in a circumferential direction on the outer side of the gas supply tube 105d.

Furthermore, a low-frequency power source 110a is attached between these electrode sections 108a, 108b, a high-voltage low-frequency voltage is applied from this low-frequency power source between the electrode sections 108a, 108b so as to make the micro-plasma MP to be generated in the etching gas G that passes through within the gas supply tube 105d via these electrode sections 108a, 108b. That is, the high-voltage low-frequency voltage to be applied between the electrode sections 108a, 108b of the LF application section 108 is dielectric barrier discharge that generates high-voltage AC excited plasma in the etching gas and an AC high voltage of about 10 kVp-p in voltage and 8 kHz in frequency is regarded as a primary factor for generation of the micro-plasma MP.

### <Stage>

The wafer support table 22 is installed vertically under the opening 105c of this plasma processing chamber 12 while being housed in the plasma processing chamber 12 and setting an axial direction thereof along the up-down direction of the plasma processing chamber 12. That is, this wafer support table 22 is installed at a position leaving a space downward from this gas supply port 105e by a predetermined space and so forth while concentrically positioning a later described RF application plate 106d relative to the gas supply port 105e of the plasma processing chamber 12. That is, this wafer support table 22 is attached in the plasma processing chamber by leaving a space of such an extent that the micro-plasma MP, which is likely to spout out of the gas supply port 105e of the plasma processing chamber 12 via the nozzle 107, does not directly strike against the RF application plate 106d on the wafer support table 22.

Specifically, the wafer support table 22 possesses a columnar main body section 106a and is installed in a state of setting the axial direction of the main body section 106 along the up-down direction. An upper end surface of this main body section 106a is made to be a blockaded and flat disk-shaped installation surface 106b and is configured so that the wafer 18 is installed on this installation surface 106b. That is, the main body section 106a is formed into an outer diameter size that is slightly larger than the outer diameter size of the wafer 18 and the installation surface 106b is made to be the one having the diameter size that is slightly larger than the outer diameter size of the wafer 18.

This installation surface 106b possesses an insulation plate 106c having insulation properties, and the RF application plate 106d, which is a lower electrode as a stage plasma generation section, is laminated on this insulation plate 106c. Here, these insulation plate 106c and the RF application plate 106d each is formed into an almost disk-like shape, and the wafer 18 is installed on this RF application plate 106d. Then, the RF application plate 106d is an ion assistance section, which forms a vertical electric field E that directs downward from above in the plasma processing chamber 12 together with the LF application section 108, makes the ion sheath to be generated in this plasma processing chamber 12, makes the plasma P to be generated in the etching gas that is sent onto the wafer 18, and excites and ionizes the etching gas G.

Specifically, the RF application plate 106d makes the plasma P to be generated in a region including the wafer 18, where the high-frequency voltage (RF) of, for example, 13.56 MHz and so forth is applied and the wafer 18 is installed on this RF application plate 106d, that is, on the wafer and the surroundings thereof, excites and thereby ionizes and radicalizes CF₄, Ar and so forth, which configure the etching gas G to be sprayed to this wafer 18 into plus ions (CF₃⁺, Ar⁺) and the fluorine radicals (F). Furthermore, an electrode section 106e is provided on a lower-end side central part of this RF application plate 106d and the high-frequency voltage is applied from a high-frequency power source 110b, which has been installed outside the plasma processing chamber 12, via this electrode section 106e.

In addition, the cooling unit 109, which is a cooling section for cooling the wafer 18 to be installed on the RF application plate 106d of this wafer support table 22, is attached to the wafer support table 22. This cooling unit 109 is made to be, for example, a water-cooling type one and is of a configuration that cools the wafer 18 installed on this RF application plate 106d by cooling the RF application plate 106d via the main body section 106a and the insulation plate 106c of the wafer support table 22. Furthermore, this cooling unit 109 is housed in and attached to the control storage section Mb. Incidentally, the power source unit 110 possesses the low-frequency power source 110a and the high-frequency power source 110b.

Furthermore, a lid body 111a that blocks up a lower end of this plasma processing chamber 12 is attached to a lower part of the plasma processing chamber 12, and a vacuum formation device 111 as a vacuuming section for evacuating in the plasma processing chamber 12 is attached to this lid body 111a. Also this vacuum formation device 111 is housed in and attached to the control storage section and is of a configuration that evacuates in the plasma processing chamber 12 in a state of leaving the wafer 18 installed on the RF application plate 106d of the wafer support table 22 in the plasma processing chamber 12.

Next, a plasma etching method using the plasma processing device M of the above-mentioned first Mode will be described.

First, the minimal shuttle that the wafer 18 before etched has been housed is installed by fitting it into the docking port 82 of the front chamber Mc of the housing 102. In this state, a start switch (not shown), which is located on a predetermined position of the housing 102 such as the operation panel 81, depressed. At this time, the cooling unit 109 is driven and cooling of the wafer support table 22 is started.

Furthermore, the minimal shuttle that has been installed in the docking port 82 is opened, and the wafer 18, which is housed in this minimal shuttle, is conveyed onto the RF application plate 106d of the wafer support table 22 of the plasma processing device M by the conveyance device and is installed on it. At this time, the wafer support table 22 is in a state where, for example, the wafer support table 22 and the plasma processing chamber 12 are relatively moved up and down, and thereby the wafer support table 22 has been taken out of the inside of the plasma processing chamber 12.

Thereafter, the plasma processing chamber 12 of the plasma processing device M is closely sealed by the lid body 111a, the inside of the plasma processing device 12 is almost evacuated by the vacuum formation device 111 until. In this state, the etching gas G is supplied into the plasma processing chamber 12 through the gas supply port 105e via the metal tube 105f attached to the gas supply port 105e of the plasma processing chamber 12, and the pressure in this plasma processing chamber 12 is maintained at a predetermined pressure. Thereafter, the low-frequency power source 110a is turned on, the low-frequency voltage is applied between the electrode sections 108a, 108b of the LF application section 108, and the high-frequency power source 110b is turned on, the high-frequency voltage is applied to the RF application plate 106d via the electrode section 106e, an electric potential gradient that is set along a direction toward the wafer 18 is formed in the plasma processing chamber 12 and the vertical electric field E is formed as shown in FIG. 14.

As a result, when the etching gas G passes between the electrode sections 108a, 108b of the LF application section 108, the micro-plasma MP is generated in the etching gas G with the low-frequency voltage that is applied between these electrode sections 108a, 108b, fluorine in CF₄ that configures this etching gas G is radicalized and thereby the large amount of fluorine radicals (F) is generated. That is, CF₄ in this etching gas G is divided (CF₄+e→CF₃+F+e) into CF₃ and F and the large amount of fluorine radicals (F) is generated. In addition, this fluorine radical passes through the respective gas insertion through holes 107b in the nozzle 107 attached to the gas supply port 105e together with the etching gas G, and thereby a spraying direction is rectified almost in parallel and it is sprayed onto the wafer 18 almost uniformly.

Furthermore, the plasma P is generated around this RF application plate 106d with the high-frequency voltage that has been applied to the RF application plate 106d of the wafer support table 22, and the electric field E is formed around this RF application plate 106d together with the ion sheath that has been set along the up-down direction. As a result, the radicalized fluorine radicals (F) are vertically sprayed onto the wafer 18 together with the plus ions (CF₃⁺, Ar⁺) that have been excited and ionized immediately before the etching gas G that has been spouted out of the nozzle 107 is thrown onto the wafer 18, and the wafer 18 is plasma-etched (anisotropically etched) via the resist pattern provided on this wafer 18.

That is, the fluorine radicals (F) originated from the micro-plasma MP are supplied onto the wafer 18 in large amount with the low-frequency voltage that has been applied between the electrode sections 108a, 108b of the LF application section 108 and the high-frequency voltage that has been applied to the RF application plate 106d, a reaction of the fluorine radicals (F) to the single crystal silicon (Si) that configures this wafer 18 is made efficient and the ions (plus ions) having plus charges such as Ar⁺, CF₃⁺ and so forth in the etching gas G are transported onto the wafer 18, and the reaction of the fluorine radicals (F) to the single crystal silicon (Si) that configure this wafer 18 is assisted and is made highly efficient, single crystal silicon bonding (Si—Si) on this wafer 18 surface is cut and it is gradually plasma-etched.

At this time, on the surface of the wafer 18, the single crystal silicon (Si) that configures this wafer 18 reacts (Si [a solid]+4F→SiF₄ [gas]) with the fluorine radicals (F) and plasma etching of this wafer 18 surface progresses. Furthermore, on the surface of the wafer 18, Ar and CF₄ and so forth in the etching gas G are excited and ionized (Ar⁺, CF₃⁺) and the reaction of the single crystal silicon that configures the wafer 18 with the fluorine radicals (F) is accelerated with ion assistance by these plus ions, and the etching reaction of the wafer 18 surface is enhanced and speeded up.

Thereafter, after etching of the wafer 18 has been completed, sealing of the plasma processing chamber 12 is released, the wafer support table 22 is taken out from within the plasma processing chamber 12, for example, by relatively moving up and down the wafer support table 22 and the plasma processing chamber 12 and so forth, the wafer 18, which is installed on the RF application plate 106d of this wafer support table 22, is installed onto the minimal shuttle by a pulling-back operation by the conveyance device, and then the minimal shuttle is close-operated and the wafer 18 is housed therein. Furthermore, the wafer 18 is carried out by detaching the minimal shuttle, where this wafer 18 is housed, from the docking port 82 of the front chamber Mc. Thereafter, driving of the cooling unit 109 is stopped and cooling of the wafer support table 22 is stopped.

As described above, in the plasma processing device M of the above-mentioned first mode, the etching gas G is supplied from the gas supply tube 105d into the plasma processing chamber 12 while evacuating the plasma processing chamber 12 by the vacuum formation device 111 in a state of leaving the wafer 18 installed on the RF application plate 106d of the wafer support table 22. In this state, the high-voltage AC excited plasma (the micro-plasma MP) is generated in the etching gas G to be sprayed from the nozzle 107, attached to the leading end side in the gas supply tube 105d, to the wafer 18 by the dielectric barrier discharge with the low-frequency voltage that has been applied between the electrode sections 108a, 108b of the LF application section 108 and the large amount of fluorine radicals (F) is generated in the etching gas G.

Then, this large amount of fluorine radicals passes through the respective gas insertion through holes 107b in the nozzle 107 together with the etching gas G, and thereby the spraying direction is rectified in the almost vertical direction and densities of these fluorine radicals and the etching gas G are made almost uniform. It was configured that thereafter, while exciting CF₄, Ar and so forth in the etching gas with the plasma P, which has been generated in the etching gas G, which is present on the wafer 18 installed on this RF application plate 106d and in the surroundings thereof, with the high-frequency voltage that has been applied to the RF application plate 106d of the wafer support table 22 and has been excited ion-sheathing with the vertical-direction electric field E formed on the wafer 18, the radicalized fluorine radicals (F) are thrown against the surface of the wafer 18 almost vertically together with ionized CF₃⁺, Ar⁺ and thereby it is etched.

As a result, the fluorine radicals (F) can be conveyed up to the surface of the wafer efficiently owing to an effect of a gas flow of the etching gas that is spouted out of the nozzle 107, by making the micro-plasma MP to be generated in the gas supply tube 105d with the low-frequency voltage that has been applied between the electrode sections 108a, 108b of the LF application section 108. In addition, the fluorine radicals (F) originated from the micro-plasma MP can be thrown onto the wafer 18 in large amount consequently, with addition of a gas conveying effect of the nozzle 107, and simultaneously the plus ions of CF₃⁺, Ar⁺ and so forth generated by exciting CF₄ and Ar in the etching gas G with the high-frequency voltage, which has been applied to the PF application plate 106d of the wafer support table 22, can be thrown onto the wafer 18. Accordingly, the reaction of the fluorine radicals with the single crystal silicon (Si) that configures the wafer 18, that is, cutting (plasma etching) of the single crystal silicon bonding (Si—Si) on the wafer 18 surface can be performed efficiently and at a high speed under assistance by these plus ions.

Here, by cooling the wafer 8 that has been installed on the RF application plate 106d of the wafer support table 22 by the cooling unit 109 and keeping the nozzle 107 for spraying the etching gas G onto the wafer 18 away from the RF application plate 106d, the micro-plasma MP generated in the gas supply tube 105d does not strike directly against the wafer 18, resist damage caused by plasma irradiation is prevented, and the large amount of fluorine radicals (F) that generated in this gas supply tube 105d can be sprayed onto the wafer 18 in large amount together with spraying out of the etching gas G from the nozzle 107. In addition, simultaneously, since temperature rising of the wafer 18 during performing etching by throwing the etching gas G onto the wafer 18 together with this large amount of fluorine radicals can be appropriately suppressed, and burning and so forth of, for example, the resist pattern that has been laminated on the wafer 18, can be prevented, this wafer 18 can be more efficiently etched.

Furthermore, since when the etching gas G passes through the respective gas insertion through holes 107b in the nozzle 107, the spraying direction of this etching gas G is made almost parallel and rectified, the etching gas G and the radicals can be thrown onto the wafer 18 almost uniformly by this nozzle 107. In addition, the plasma P is generated in the etching gas G, which is present on the wafer 18 that has been installed on this RF application plate 106d and in the surroundings thereof, with the high-frequency voltage that has been applied to the RF application plate 106d of the wafer support table 22, and the etching gas G can be efficiently excited, ionized and radicalized at the position directly before the etching gas G is thrown against the wafer 18. Thereby, since the etching gas G to be sprayed from the nozzle 107 to the wafer 18 can be more efficiently ionized and radicalized, even the comparatively small half-inch size wafer 18 can be efficiently etched.

In addition, since the densities of the etching gas G, which has passed through the respective gas insertion through holes 107b in this nozzle 107, can be made almost uniform and the etching gas G can be uniformly sprayed to the wafer 18 by using the nozzle 107 configured so that the plurality of linear gas insertion through holes 107b are provided in parallel and at equal intervals, the wafer 18 can be efficiently etched by using the nozzle 107 having the comparatively simple configuration.

Incidentally, in the above-mentioned first mode, it has been made to be a configuration in which the etching gas G supplied from the gas supply tube 105d is sprayed onto the wafer 18 almost uniformly by the nozzle 107 where the plurality of gas insertion through holes 107b have been provided in parallel and at equal intervals. However, as in another mode shown in FIG. 17, the etching gas G supplied through the gas insertion through holes 107b can be sprayed onto the wafer 18 almost uniformly even when it is made to be the nozzle 107 that an accumulation in parallel and at equal interval with plurality of cylindrical tube bodies 112, in whose central parts the gas insertion through holes 107b have been opened. In this case, since necessity of providing the plurality of gas insertion through holes 107b in the main body section 107a is eliminated, the nozzle 107, which can etch the wafer 18 with accuracy, can be configured more simply. In addition, it can be also made to be configurations in which the gas supply tube 105d of the plasma processing chamber 12 is made into a tubular shape and a plurality of gas supply holes (not shown) have been formed, and the plurality of nozzles 107 have been attached to the gas supply port 105e of this gas supply tube 105d. In particular, in the above-mentioned first mode, as a result of experiments, since the etching rate can be made as high as about 500 nm/min maximally, processing of the wafer 18 that is obviously excellent technically is possible in comparison with the case of the later described second mode.

### [Second Mode]

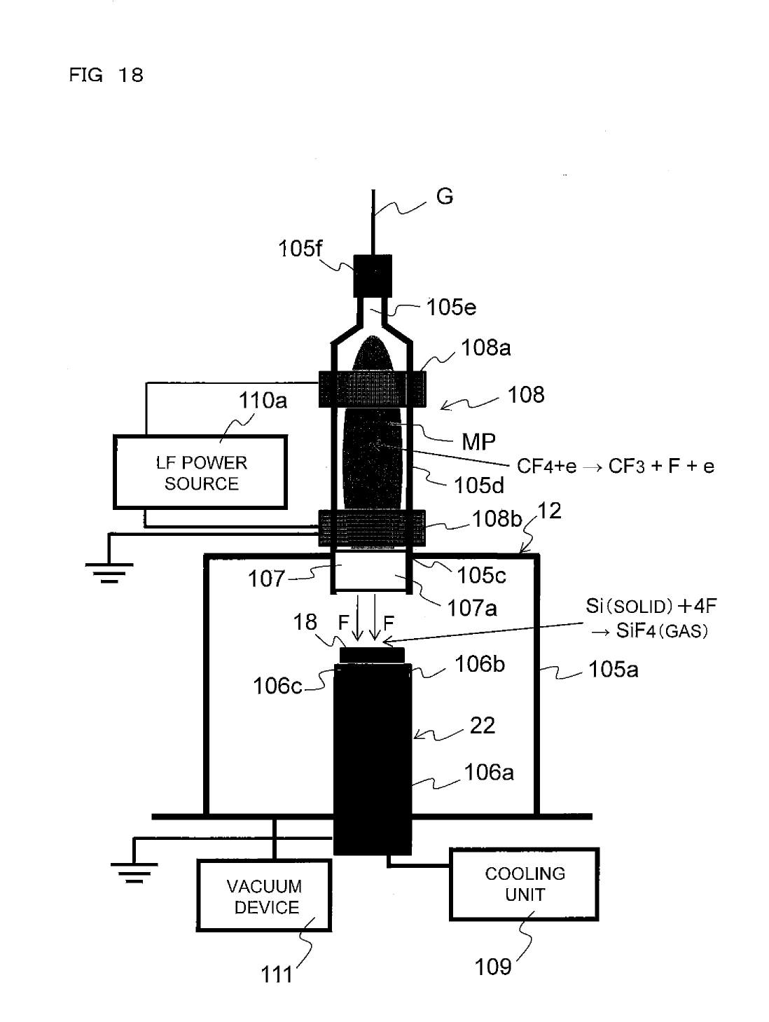

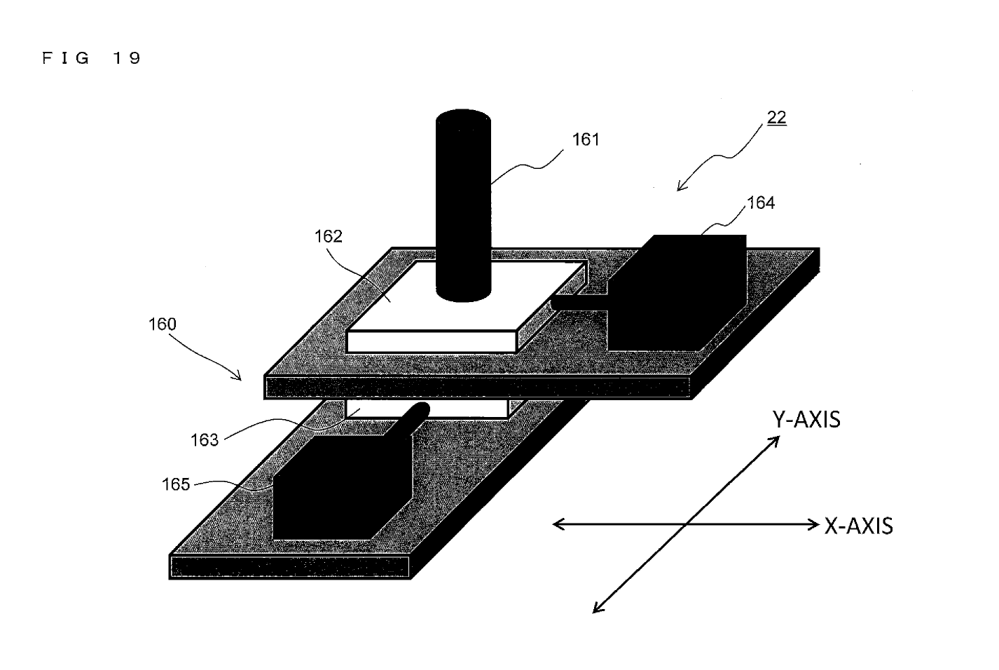

FIG. 18 is a schematic diagram showing a plasma processing device according to the second mode related to the present invention.

The present second mode is different from the first mode in that while the first mode is the configuration in which the RF application plate 106d, which applies the high-frequency voltage to the wafer 18 to be installed on the wafer support table 22, is provided, the second mode is the configuration in which the RF application plate 106d is not provided and the wafer 18 is plasma-etched only with the high-voltage AC excited plasma. That is, in the plasma processing device M according to the second mode, as shown in FIG. 18, although the plasma processing chamber 12 is configured similarly to that in the first mode, the structure of the wafer support table 22 is different from that in the first mode. Specifically, in the wafer support table 22, the insulation plate 106c is installed on the installation surface 106b and the wafer 18 is installed on this insulation plate 6c.

Then, in this plasma processing device M, the cooling unit 109 is driven and cooling of the wafer support table 22 is started, and the wafer 18 is installed on the insulation plate 106c of the wafer support table 22. Thereafter, similarly to the first mode, the plasma processing chamber is sealed, the inside of the plasma processing chamber 12 is evacuated by the vacuum formation device 111. In this state, after the etching gas G has been supplied into the plasma processing chamber 12 through the gas supply port 105e in the plasma processing chamber 12, the low-frequency power source 110a is turned on and the low-frequency voltage is applied between the electrode sections 108a, 108b of the LF application section 108.

As a result, when the etching gas G passes between the electrode sections 108a, 108b of the LF application section 108, the micro-plasma MP is generated in the etching gas G with the low-frequency voltage that is being applied between these electrode sections 108a, 108b. At this time, CF₄ in the etching gas is separated into CF₃ and F and the large amount of fluorine radicals (F) is generated.

In addition, when the etching gas G passes through the respective gas insertion through holes 107b in the nozzle 107, the spraying direction is rectified almost in parallel and it is sprayed onto the wafer 18 almost uniformly and the wafer 18 is gradually plasma-etched via the resist pattern provided on this wafer 18. At this time, on the surface of the wafer 18, the single crystal silicon (Si) that configures this wafer 18 reacts (Si [the solid]+4F→SiF₄ [the gas]) with the fluorine radicals (F), and plasma-etching of this wafer 18 surface progresses.

The second mode configured as described above can generate the micro-plasma MP in the etching gas G with the low-frequency voltage, which has been applied between the electrode sections 108a, 108b of the LF application section 108, can throw the large amount of fluorine radicals (F) onto the wafer almost uniformly, with the spraying direction of the etching gas G being rectified almost in parallel when passing through the respective gas insertion through holes 107b in the nozzle 107, and can etch the wafer 18 via the resist pattern provided on this wafer 18 with accuracy.

In particular, in the present second mode, as the result of experiments, in a case where the pressure in the plasma processing chamber 12 is in the vicinity of several kPa from the atmospheric pressure, the etching rate becomes 5 to 10 μm/min, the plasma density is high, a plasma column spouts out and is directly radiated onto the wafer 18, and it is feared that the resist pattern on the wafer 18 may be damaged. Therefore, although it is not suited for etching of the wafer 18 that the resist pattern has been laminated, local etching of a bare wafer and so forth of a single crystal silicon simple substance is possible.

In contrast, in a case where the pressure in the plasma processing chamber 12 has been set from several hundred Pa to the vicinity of 1 kPa, although the etching rate is low and becomes about 30 nm/min, it can be applied to etching of the wafer 18 that the resist pattern has been laminated thereon. In this case, heat generation of the wafer 18 is little and the resist pattern can be kept without cooling the wafer 18 by the cooling unit 109 upon etching. However, in comparison with a case where the wafer 18 has been cooled by the cooling unit 109 upon etching, it is feared that the resist pattern may change in quality, and therefore it is feared that time and labor may be taken for delaminating (ashing) the resist pattern.

Furthermore, in a case where the pressure in the plasma processing chamber 12 has been evacuated to not more than 1 kPa, since the micro-plasma MP diffuses on the downstream side of the gas supply tube 105d and the fluorine radicals can be supplied to the wafer 18 surface, etching of the wafer 18 that the resist pattern has been laminated thereon becomes possible. However, in this case, when the distance between the gas supply tube 105d and the wafer 18 is made too close (for example, less than 5 mm), it is feared that the resist pattern on the wafer 18 may be broken.

### [Third Mode]

FIG. 19 is a schematic diagram showing part of a plasma processing device according to the third mode of the present invention.

The third mode related to the present invention is different from the above-mentioned first mode in that while the first mode is the fixed type wafer support table 22, the third mode makes it to be the mobile-type wafer support table 22 and upon plasma-etching, the wafer 18 is scanned by moving the wafer support table 22. That is, in the plasma processing device M according to the third mode, the configurations other than that of the wafer support table 22 are made the same as the configuration of the above-mentioned first mode, and the structure of the wafer support table 22 is different from that in the first mode as shown in FIG. 19.

Specifically, the wafer support table 22 possesses a wafer holder 161 on which the wafer 18 is installed. A scanning mechanism 160 as a scanning section, which possesses an X-axis stage 162 to move the wafer holder 161 in the X-axis direction and a Y-axis stage 163 to move the wafer holder 161 in the Y-axis direction, is attached to the wafer holder 161. The scanning mechanism 160 moves the wafer holder 161 respectively in the X-axis direction and the Y-axis direction that intersect with the spraying direction of the etching gas G from the nozzle 107. A straight advancing motor 164 is attached to the X-axis stage 162 as a drive source that moves the wafer holder 161 in the X-axis direction via the X-axis stage 162. A straight advancing motor 165 is attached also to the Y-axis stage 163 as a drive source that moves the wafer holder 161 in the Y-axis direction via the Y-axis stage 163.

From the above, in the plasma processing device M of the present third mode, when plasma-etching the wafer 18 that has been installed on the wafer holder 161, driving of the respective straight advancing motors 164, 165 of the scanning mechanism 160 is appropriately controlled so as to make it scan an etching point on the wafer 18 in the X-axis direction and the Y-axis direction. As a result, it becomes possible to uniform non-uniformity of the etching rates in the wafer 18 surface, non-uniformity which would occur depending on the plasma density fluctuations, sizes and device configurations and so forth. That is, uniform etching of the wafer 18 surface becomes possible by controlling a scanning speed and a scanning pattern and so forth by the scanning mechanism 160 upon plasma-scanning and adjusting a time for exposing it to a downstream sector of the micro-plasma MP that is large in etching rate per part of the wafer 18 surface.

Here, in the conventional mega fabrication using a wafer of a large diameter of about 12 inches, since the target wafer to be plasma-etched is large, it is impossible to scan the wafer upon plasma-etching. On the other hand, in the plasma processing device M, since it targets on the circular wafer 18 of 12.5 in diameter (the half-inch size), scanning of the wafer 18 upon plasma-etching becomes possible and uniformization of the etching rates in the wafer 18 surface is possible.

### [Fourth Mode]

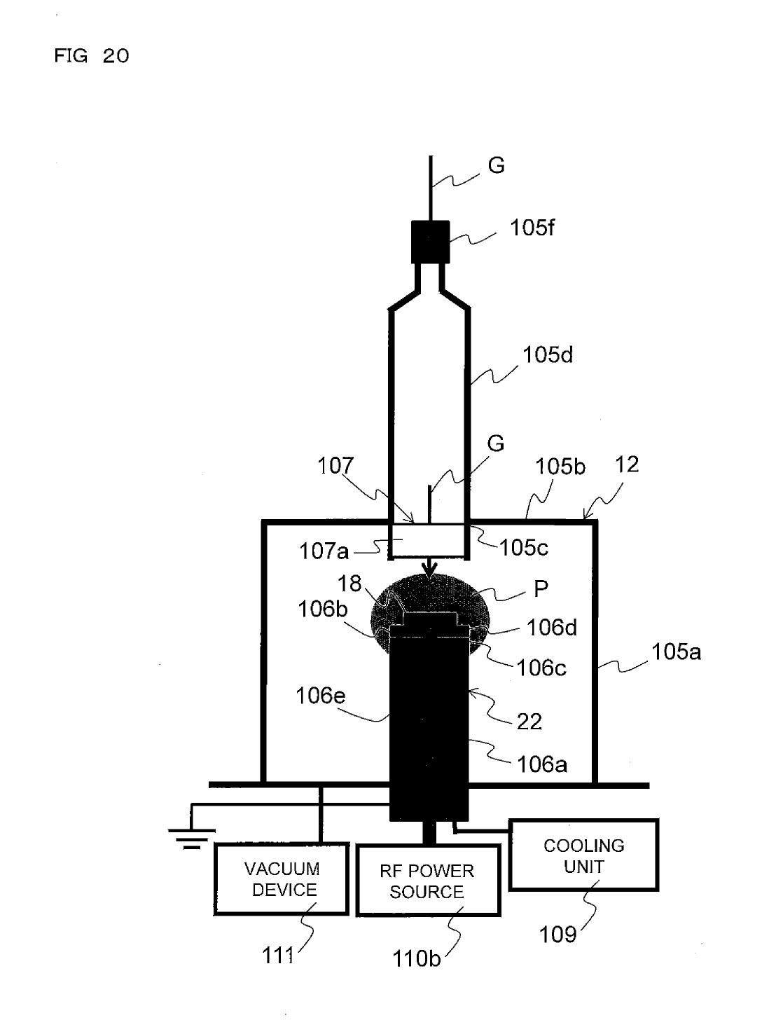

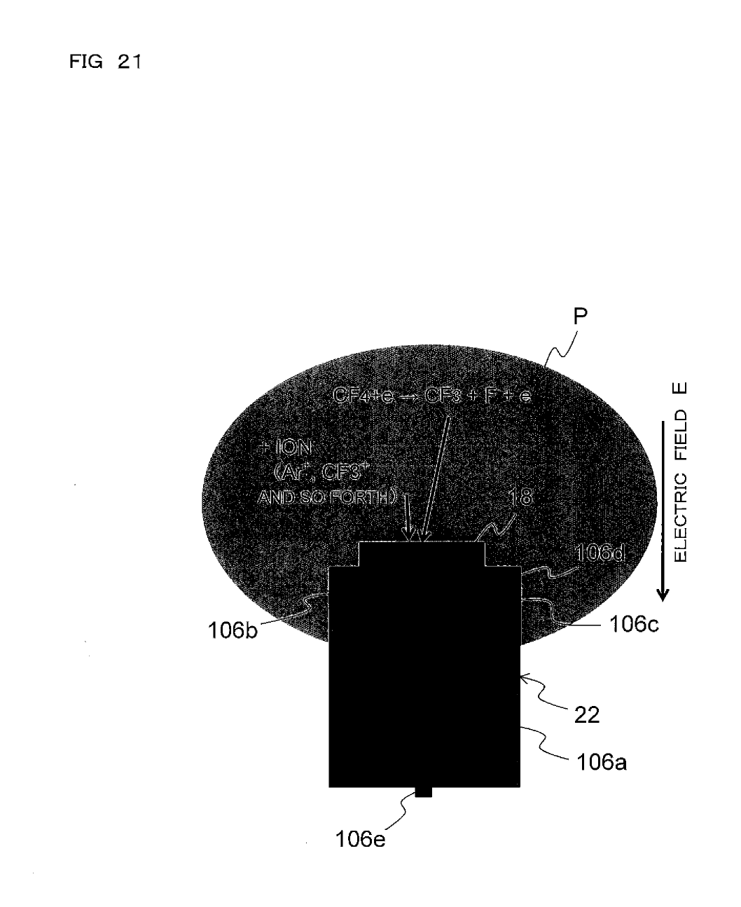

FIG. 20 is a schematic diagram showing a plasma processing device according to the fourth mode related to the present invention. FIG. 21 is an explanatory diagram showing a state where the wafer is being etched by the plasma processing device.

The present fourth mode is different from the above-mentioned first mode in that while the first mode is of the configuration in which the LF application section 108 is provided in the gas supply tube 105d of the plasma processing chamber 12, the fourth mode is the configuration in which the LF application section 108 is not provided, and the wafer is etched only with stage RF plasma. That is, in the plasma processing device M according to the fourth mode, as shown in FIG. 20, although the wafer support table 22 is configured similarly to that in the first mode, the structure of the plasma processing chamber 12 is different from that of the first mode. Specifically, the respective electrode sections 108a, 108b of the LF application section 108 are not attached to the gas supply tube 105d of the this plasma processing chamber 12, and the etching gas G, which has been supplied from this gas supply tube 105d and has passed through the nozzle 107, is sprayed to the wafer 18 that has been installed on the RF application plate 106d of the wafer support table 22.

Then, in this plasma processing device M, the cooling unit 109 is driven and cooling of the wafer support table 22 is started, and the wafer 18 is installed on the RF application plate 106d of the wafer support table 22. Thereafter, similarly to the above-mentioned first mode, the plasma processing chamber 12 is sealed and the inside of this plasma processing chamber 12 is evacuated by the vacuum formation device 111. In this state, after the etching gas G has been supplied into the plasma processing chamber 12 through the gas supply port 105e in the plasma processing chamber 12, the high-frequency power source 110b is turned on and the high-frequency voltage is applied to the RF application plate 106d via the electrode section 106e.

Furthermore, when the etching gas G passes through the nozzle 107, the spraying direction of this etching gas G is rectified almost in parallel, and it is sprayed onto the wafer 18. At this time, in this etching gas G, the plasma P is generated in the etching gas G with the high-frequency voltage that is applied to the RF application plate 106d of the wafer support table 22, and the wafer 18 is plasma-etched via the resist pattern provided on the wafer 18.

Also, at this time, on the wafer 18, CF₄ in the etching gas G is separated into CF₃ and F with the high-frequency voltage that is applied to the RF application plate 106d, and the fluorine radicals (F) are generated. Furthermore, on the wafer 18, argon gas and CF₄ and so forth in the etching gas G are ionized (Ar⁺, CF₃⁺) and the reaction (Si [the solid]+4F→SiF₄ [the gas]) of the silicon (Si) that configures the wafer 18 with the fluorine radicals (F) is enhanced and the etching reaction of the wafer 18 surface is accelerated.

The fourth mode configured as described above can generate the plasma P in the etching gas G with the high-frequency voltage that is applied to the RF application plate 106d of the wafer support table 22, can rectify the spraying direction almost in parallel when passing through the respective gas insertion through holes 107b in the nozzle 107, and can spray the etching gas G onto the wafer 18 almost uniformly. Accordingly, the wafer 18 can be etched with accuracy via the resist pattern provided on this wafer 18.

In particular, in the fourth mode, as a result of experiments, in a case where the pressure in the plasma processing chamber 12 is higher than 2 kPa, the plasma P cannot be generated in this plasma processing chamber 12 and therefore the inside of this plasma processing chamber 12 should be evacuated to the pressure of not more than 2 kPa at which discharge becomes possible. That is, in a case where the pressure in the plasma processing chamber 12 is not more than 2 kPa and the etching rate is about 150 nm/min maximally, etching of the wafer 18 on which the resist pattern has been laminated becomes possible by cooling the wafer 18 by the cooling unit 109. In contrast, in a case of not cooling the wafer 18 by the cooling unit 109, since the resist resistance is poor and a change in quality of the resist pattern is feared, it is feared that the time and labor may be taken for delaminating (ashing) the resist pattern.

### <Others>

Incidentally, in each of the above-mentioned modes, the configuration is made so that the wafer 18 on which the resist pattern is laminated is etched at least by using application of the low-frequency voltage between the electrode sections 108a, 108b of the LF application section 108. However, each mode is not limited to this and it can be used for even the one other than the wafer 18 of the single crystal silicon structure with the resist pattern being laminated thereon correspondingly.

In addition, by making the configuration such that the gas supply tube 105d is made movable relative to the plasma processing chamber 12 and the wafer 118 is scanned by scanning this gas supply tube 105d in the horizontal direction, and by making the configuration such that the gas supply tube 105d is made large in diameter and the plurality of nozzles 107 are attached thereto so as to rectify the etching gas G, it can be used for even the large diameter wafer 18 that is larger than the minimal wafer of the half-inch size correspondingly.

### Embodiment 1

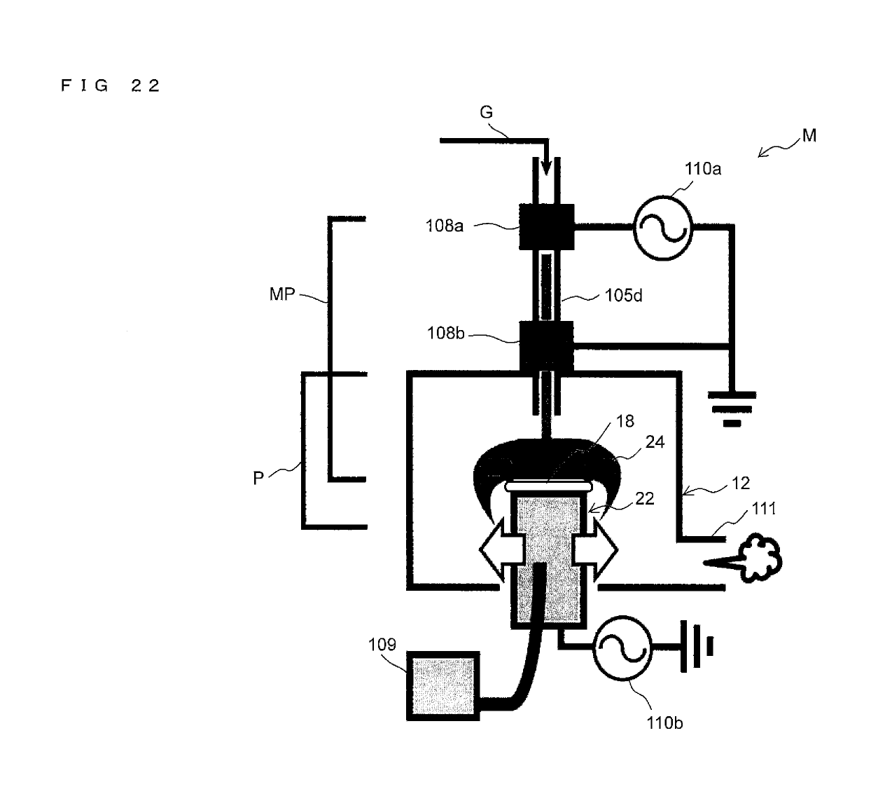

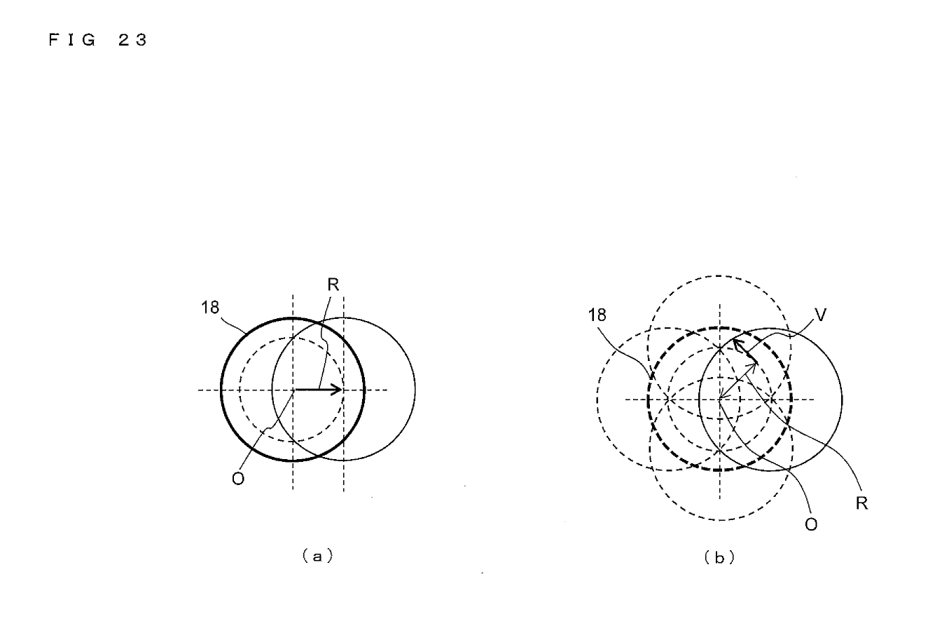

Next, embodiments 1 to 6 of the plasma processing device related to the present invention will be described with reference to FIG. 22 and FIG. 23.

FIG. 22 is a schematic diagram showing the plasma processing device M according to the embodiments 1 to 6 of the present invention. FIG. 23 are diagrams showing scanning conditions of the wafer 18 by the plasma processing device M according to the embodiments 1 to 6, in which FIG. 23(a) is a movement by a distance R from an initial position C and FIG. 23(b) is rotational scanning of a radius R.

As shown in FIG. 22, in the plasma processing device M according to each embodiment, the nozzle 107 that is 6 mm in outer diameter and 4 mm in inner diameter is used and the pressure in the plasma processing chamber 12 is set to 180 Pa. In addition, the configuration is made so that the RF application plate 106d is cooled by the cooling unit 109 while applying the low-frequency voltage of 8 kHz between the electrode sections by the low-frequency power source 110a and applying the high-frequency voltage of 13.56 MHz to the RF application plate 106d by the high-frequency power source 110b.

As the etching gas G, CF₄/Ar gas (CF₄: 35 sccm, Ar: 85 sccm) is used and so-called RF power is set to 25 W. The scanning condition by the scanning mechanism 160 is such that as shown in FIG. 23(a) and FIG. 23(b), the wafer 18 is rotationally scanned (no autorotation of the wafer 18) by setting a linear velocity V in a case where it has been moved by the radius (the distance) R=4 mm from the initial position (the central position) O of the wafer 18 to 2 mm/s. In each embodiment, it is made to be the wafer 18 of 12.5 mm in outer diameter, a range from an outer peripheral edge of the wafer 18 to 0.5 mm is pressed by the clamp 24 and is set as a pressing margin, and the etching rate is measured at intervals of 1 mm in regard to a region of 5 mm from the central position O of the wafer 18.

Then, in confirmation of the RF addition effect, the etching rate [mm/min] relative to the position [mm] of the wafer 18 was measured in regard to each of a case where the wafer 18 is not scanned by the scanning mechanism 160, and only the micro-plasma was turned ON by applying the low-frequency voltage between the electrode sections 108a, 108b (the embodiment 1), a case where only RF was turned ON by applying the high-frequency voltage to the RF application plate 106d (the embodiment 2), and a case where both were turned ON by applying the low-frequency voltage between the electrode sections 108a, 108b and applying the high-frequency voltage to the RF application plate 106d (the embodiment 3).

As a result, as shown in FIG. 12(a), in the embodiment 1, at the average etching rate of about 10 nm/min, the distribution of small protrusion-like etching rates was obtained. In the embodiment 2, the flat etching rate distribution on the wafer 18 surface of about 40 nm/min was obtained. In the embodiment 3, although it resulted in the etching rate distribution of the Gaussian distribution-like shape, the average of the etching rates of the embodiment 3 is larger than the total of the etching rates of the above-mentioned embodiment 1 and embodiment 2 and reached 98.1 nm/min, and the obviously large etching rate could be obtained.

Accordingly, it was found that in the case where each of the micro-plasma and RF has been turned ON, the wafer 18 can be etched at a higher rate. However, in the above-mentioned embodiment 3, it resulted in the etching rate that is as large as 22.7% in non-uniformity.

Furthermore, in confirmation of the scanning effect, the etching rate [nm/min] relative to the position [mm] of the wafer 18 was measured in regard to each of a case where the wafer 18 was scanned by the scanning mechanism 160 while turning only the micro-plasma ON (the embodiment 4), a case where the wafer 18 was scanned by the scanning mechanism 160 while turning only RF ON (the embodiment 5), and a case where the wafer 18 was scanned by the scanning mechanism 160 while turning both of the micro-plasma and RF ON (the embodiment 6). As a result, as shown in FIG. 12(b), in comparison with the etching rates of the embodiment 4 and the embodiment 5, the average of the etching rates of the embodiment 6 was as large as 78.8 nm/min and the non-uniformity thereof was 3.5% and became obviously small in comparison with that of the above-mentioned embodiment 3. Accordingly, it was found that the wafer 18 can be more accurately etched by scanning the wafer 18 while turning each of the micro-plasma M and RF ON.

### REFERENCE SIGNS LIST

12 plasma processing chamber (processing chamber)
14 gate valve
15 gas supply port
16 gas exhaust port
18 semiconductor wafer (workpiece)
19 wafer support device
20 wafer pedestal
22, 22′ wafer support table
24 wafer pressing plate
25 guide groove
26 groove for spring
26a spring
28 protective tube
30 refrigerant supply tube (refrigerant supply section)
32 cooling tube
34, 34′ power supply body (power supply section)
35 lower electrode
36 wafer hold groove (wafer mount)
38 groove for arm
39 depression
40 cooling port
41 vent
42 exhaust hole
43 upper hole
44 upper ring
46 lower ring
48 external cylinder
50 first drive plate
52 first motor
54 first drive screw
56 second drive plate
58 second motor
60 second drive screw
62 lifting device
63 Z-axis direction drive plate
64 insulation spacer
66 internal conductor
67 external conductor
68 insulator
69 external electrode
70 movable washer (shielding member)
82 docking port
M plasma processing device
Ma main body section
Mb control storage section
Mc front chamber

1. A processing device for a minimal fabrication system comprising:
a wafer support device that is configured to support a wafer as a processing object;
a wafer hold section that is provided on an upper part of the wafer support device;
a processing chamber that houses therein the wafer hold section and is substantially shut off from the outside; and
a wafer processing section that is provided in the processing chamber, wherein
the wafer support device includes: the wafer hold section; a shaft that supports the wafer hold section and extends to the outside of the processing chamber; a drive section that is connected to the shaft on the outside of the processing chamber and is configured to move the shaft in XYZ axial directions; and a control device that is configured to control the drive section so that processing by the wafer processing unit is made uniform over the entire wafer surface, and
the wafer that is held by the wafer hold section is made relatively movable over the entire wafer surface relative to the wafer processing section in the processing chamber by operation of the drive section.

2. The processing device for a minimal fabrication system according to claim 1, wherein
a hole of a range within which the shaft is movable in the XYZ axial directions is provided in the bottom of the processing chamber, and a shield member that fills up a gap between the edge of the hole on the processing chamber and the shaft is provided so as to prevent movement of the wafer hold section from disturbing in the XYZ directions.

3. The processing device for a minimal fabrication system according to claim 2, wherein
the shield member includes a plurality of movable washers that are different from one another in opening size.

4. The processing device for a minimal fabrication system according to claim 1, wherein
the wafer hold section has a wafer pedestal, a wafer support table and a wafer pressing plate,
the wafer pedestal includes a wafer mount that is configured to mount the wafer, which is conveyed into the processing chamber,
the wafer support table is provided on an upper end part of the shaft, moves up and down so as to press the wafer, which is mounted on the wafer mount, against the pressing plate as the shaft is raised by the drive section, and
the wafer pressing plate is configured to press a peripheral part of the wafer that is raising, fix, and support the wafer in cooperation with the wafer support table.

5. The processing device for a minimal fabrication system according to claim 1, wherein
the wafer processing section is composed of a plasma processing section, which includes a micro-plasma generation section that is configured to supply micro-plasma to the processing chamber, and an RF plasma generation section that is provided in the processing chamber and configured to superimpose a high frequency on the generating micro-plasma, and
the wafer support device is composed of a power supply section that is configured to supply power to the RF plasma generation section, and a refrigerant supply section that is configured to supply a refrigerant for cooling the wafer and the power supply section, the both of which are in the shaft of the wafer support device.

6. The processing device for a minimal fabrication system according to claim 5, wherein
the outer side of the shaft of the wafer support device is a protective tube that supports the wafer pedestal, and a refrigerant supply tube that supports the wafer support table is provided in the protective tube as the refrigerant supply section,
the refrigerant supply tube supports the wafer support table so as to be freely movable in the protective tube in an axial direction thereof, and
a cooling tube that houses therein an inert gas and a refrigerant for cooling the inert gas, and a power supply body for supplying power to the RF plasma generation section are housed in the refrigerant supply tube.

7. The processing device for a minimal fabrication system according to claim 6, wherein
the cooling tube is looped around the power supply body, and the refrigerant is supplied into the cooling tube so as to be supplied from the drive section side to the electrode side of the RF plasma generation section and then again returned to the drive section side.

8. The processing device for a minimal fabrication system according to claim 5, wherein
the power supply section supports the wafer support table by being made into a double structure of an outer tube and an inner tube provided inside the outer tube, and an electrode of the RF plasma generation section is connected to an upper end of the power supply section, and
an internal space of the inner tube communicates with a gap space between the inner tube and the outer tube and thereby a passage of a refrigerant for cooling is configured so as to cool the power supply section and the electrode.

9. The processing device for a minimal fabrication system according to claim 6, wherein
an upper ring that surrounds the hole is attached to the bottom of the processing chamber, the protective tube that supports the wafer pedestal passes through the upper ring and is extended to the outside of the processing chamber, and a lower ring is connected to the upper ring, through the intermediary of an external cylinder that flexibly deforms,
the protective tube passes through the external cylinder and one end thereof is connected and fixed to the drive section together with the lower ring, the drive section is fixed to the lower ring and supports a lower end of the refrigerant supply tube,
the wafer support table that is supported by the refrigerant supply tube is configured to be moved in an axial direction of the protective tube by the drive section in order to support and fix the wafer, and
the protective tube is configured to be moved scanningly by the drive section in a direction that intersects with the axis of the protective tube.

10. The processing device for a minimal fabrication system according to claim 1, wherein
the wafer is a half-inch size semiconductor wafer and the wafer processing section is a plasma processing section.
